(19) United States
(12) Patent Application Publication
(10) Pub. No.: US 2025/0143099 A1
(43) Pub. Date: May 1, 2025

(54) DISPLAY PANEL AND DISPLAY DEVICE INCLUDING THE SAME

(71) Applicant: Samsung Display Co., Ltd., Yongin-si (KR)

(72) Inventors: BEOMSOO PARK, Yongin-si (KR); JONGSEOK KIM, Yongin-si (KR); DONGHUN NAM, Yongin-si (KR); JUNGMAN MOON, Yongin-si (KR); Eunji LIM, Yongin-si (KR); JAEIK LIM, Yongin-si (KR)

(21) Appl. No.: 18/769,146

(22) Filed: Jul. 10, 2024

(30) Foreign Application Priority Data
Oct. 26, 2023 (KR) 10-2023-0144352

(51) Int. Cl. H10K 59/124; H10K 59/121

(52) U.S. Cl. CPC H10K 59/124; H10K 59/1213

(57) ABSTRACT

A display panel includes a base layer including a boundary region extending in a first direction, a first pixel region adjacent to the boundary region in a second direction, and a second pixel region spaced apart from the first pixel region with the boundary region therebetween, lower insulating layers above the base layer, and defining a valley hole corresponding to the boundary region, a first conductive pattern including a portion inside the valley hole, a first organic layer including a portion above the lower insulating layers, and a portion covering the first conductive pattern and filling the valley hole, pixel circuits respectively overlapping the first and second pixel regions, light-emitting elements above the first organic layer, respectively overlapping the first and second pixel regions, and respectively electrically connected to the pixel circuits, and a second conductive pattern above the first organic layer, and including a portion overlapping the boundary region.

### CROSS-REFERENCE TO RELATED APPLICATIONS

The present application claims priority to, and the benefit of, Korean Patent Application No. 10-2023-0144352, filed on Oct. 26, 2023, in the Korean Intellectual Property Office, the entire disclosure of which is incorporated herein by reference.

### BACKGROUND

### 1. Field

The present disclosure herein relates to a display panel and a display device of which shapes may be changed.

### 2. Description of the Related Art

Multimedia electronic devices, such as televisions, smartphones, tablet computers, navigation systems, or game consoles, may be provided with a display device for displaying an image. The display device generates the image, and may be provided with a display panel for supplying the generated image to a user. The display panel may include a plurality of pixels for generating the image, and a driver for driving the pixels.

With recent technological development, a flexible display device including a flexible display panel is being developed. For example, there are being developed various flexible display devices that are changeable, foldable, or rollable into a curved surface form. The flexible display device of which a shape is variously changed may be more portable, and may improve user convenience.

However, the flexible display panel may be vulnerable to an external impact, and some transistors thereof may be damaged by the external impact or a stress caused by folding, so that pixels thereof may not normally operate.

### SUMMARY

The present disclosure provides a display panel with improved impact-resistance and reliability.

One or more embodiments of the present disclosure provides a display panel including a base layer including a boundary region extending in a first direction, a first pixel region adjacent to the boundary region in a second direction crossing the first direction, and a second pixel region spaced apart from the first pixel region with the boundary region therebetween, lower insulating layers above the base layer, and defining a valley hole corresponding to the boundary region, a first conductive pattern including a portion inside the valley hole, a first organic layer including a portion above the lower insulating layers, and including a remaining portion covering the first conductive pattern and filling the valley hole, pixel circuits respectively overlapping the first pixel region and the second pixel region, light-emitting elements above the first organic layer, respectively overlapping the first pixel region and the second pixel region, and respectively electrically connected to the pixel circuits, and a second conductive pattern above the first organic layer, and including a portion overlapping the boundary region.

The pixel circuits may include a first pixel transistor overlapping the first pixel region, and a second pixel transistor overlapping the second pixel region.

The second conductive pattern electrically may connect the first pixel transistor and the second pixel transistor.

The first pixel transistor may include a first semiconductor pattern including a first source region, a first drain region, and a first channel region between the first source region and the first drain region, wherein the second pixel transistor includes a second semiconductor pattern including a second source region, a second drain region, and a second channel region between the second source region and the second drain region, wherein an end of the second conductive pattern is electrically connected to the first source region or the first drain region, and wherein another end of the second conductive pattern is electrically connected to the second source region or the second drain region.

The pixel circuits may further include a first connection electrode electrically connected to the first source region or the first drain region, wherein the first conductive pattern is at a same layer as the first connection electrode, and includes a same material as the first connection electrode.

The pixel circuits may further include a second connection electrode electrically connected to the first connection electrode, wherein the second conductive pattern is at a same layer as the second connection electrode, and includes a same material as the second connection electrode.

The first conductive pattern may contact an inner side surface of the valley hole.

The valley hole may penetrate some of the lower insulating layers, wherein an upper surface of one of the lower insulating layers of the base layer is defined as a valley hole lower surface that is covered by the first conductive pattern.

The first conductive pattern may be configured to transmit a power supply voltage.

The display panel may further include a first blocking pattern under the first conductive pattern, and overlapping a portion of the first conductive pattern on a plane.

The display panel may further include a second blocking pattern overlapping a portion of the pixel circuits on a plane, wherein the first blocking pattern is at a same layer as the second blocking pattern, and includes a same material as the second blocking pattern.

A portion of the first conductive pattern may contact an upper surface of the first blocking pattern.

The first pixel region may include a (1-1)-th pixel region and a (1-2)-th pixel region adjacent to each other in the first direction, wherein the boundary region overlaps the (1-1)-th pixel region and the (1-2)-th pixel region in the second direction.

The boundary region may be not between the (1-1)-th pixel region and the (1-2)-th pixel region.

The first conductive pattern may entirely cover the valley hole.

The first organic layer may include a layer portion above the lower insulating layers, and a filling portion in the valley hole, and having an integrated shape with the layer portion.

The lower insulating layers may include a first reference insulating layer under the first organic layer, and a second reference insulating layer under the first reference insulating layer, and
wherein the valley hole penetrates the first reference insulating layer and the second reference insulating layer.

The display panel may further include a second organic layer above the first organic layer, and covering the second conductive pattern, wherein the light-emitting elements are above the second organic layer.

In one or more embodiments of the present disclosure, a display panel includes a base layer including a boundary region extending in a first direction, a first pixel region adjacent to the boundary region in a second direction crossing the first direction, and a second pixel region spaced apart from the first pixel region with the boundary region therebetween, lower insulating layers above the base layer, and defining a valley hole corresponding to the boundary region, a first conductive pattern including a portion inside the valley hole, a first organic layer including a portion above the lower insulating layers, and including a remaining portion filling the valley hole and covering the first conductive pattern, pixel circuits respectively overlapping the first pixel region and the second pixel region, and light-emitting elements above the first organic layer, respectively overlapping the first pixel region and the second pixel region, and respectively electrically connected to the pixel circuits, wherein the first conductive pattern contacts an inner side surface of the valley hole, and is configured to transmit a power supply voltage.

In one or more embodiments of the present disclosure, a display device, including a first non-folding region, a folding region, and a second non-folding region sequentially arranged along a first direction, includes a window, a display panel under the window, and a housing under the display panel to accommodate the display panel, wherein the display panel includes a base layer including a boundary region extending in the first direction, a first pixel region adjacent to the boundary region in a second direction crossing the first direction, and a second pixel region spaced apart from the first pixel region with the boundary region therebetween, lower insulating layers above the base layer, and defining a valley hole corresponding to the boundary region, a first conductive pattern including a portion inside the valley hole, a first organic layer including a portion above the lower insulating layers, and including a remaining portion filling the valley hole and covering the first conductive pattern, pixel circuits respectively overlapping the first pixel region and the second pixel region, and light-emitting elements above the first organic layer, respectively overlapping the first pixel region and the second pixel region, and respectively electrically connected to the pixel circuits.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1A is a perspective view of a display device according to one or more embodiments of the present disclosure;

FIGS. 1B and 1C are perspective views illustrating a folded state of the display device illustrated in FIG. 1A;

FIG. 2 is an exploded perspective view of a display device according to one or more embodiments of the present disclosure;

FIG. 3 is a cross-sectional view of a display panel according to one or more embodiments of the present disclosure;

FIG. 4 is a plan view of a display panel according to one or more embodiments of the present disclosure;

FIG. 5 is an equivalent circuit view of a pixel according to one or more embodiments of the present disclosure;

FIG. 6 is an enlarged plan view of a display panel according to one or more embodiments of the present disclosure;

FIG. 7 is a cross-sectional view of a display panel according to one or more embodiments of the present disclosure;

FIGS. 8A to 8G are plan views, according to a stack sequence, of patterns of a pixel according to one or more embodiments of the present disclosure;

FIG. 9 is a cross-sectional view of a display panel according to one or more embodiments of the present disclosure;

FIG. 10A is a plan view of some configurations of a display panel according to one or more embodiments of the present disclosure; and

FIGS. 10B and 10C are cross-sectional views of a display panel according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

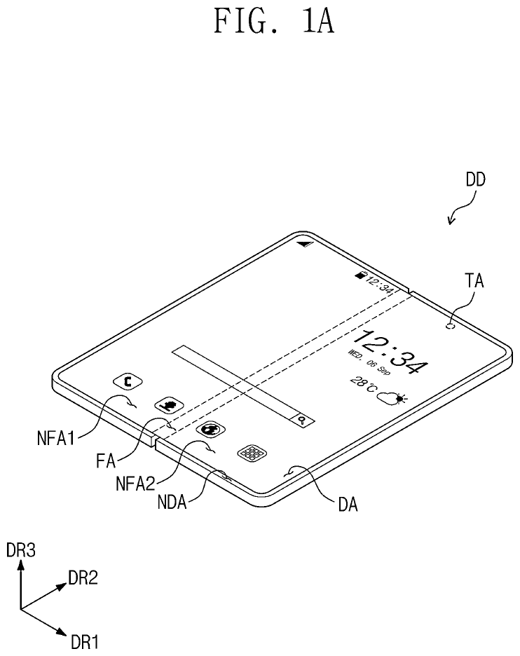

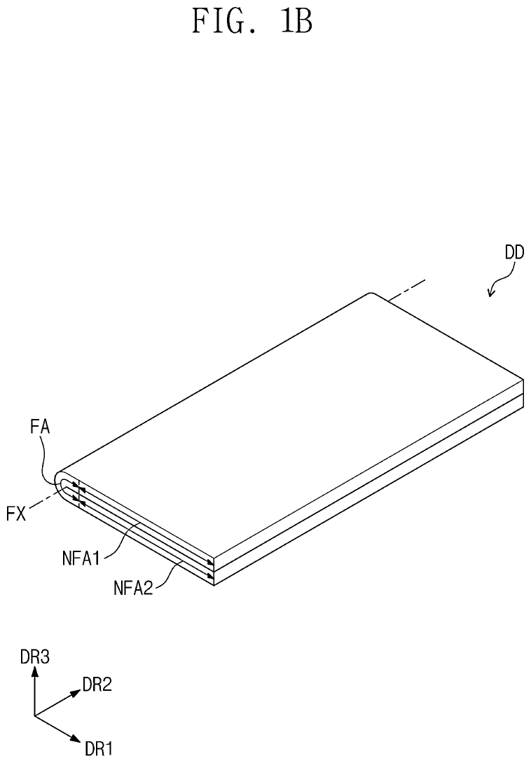

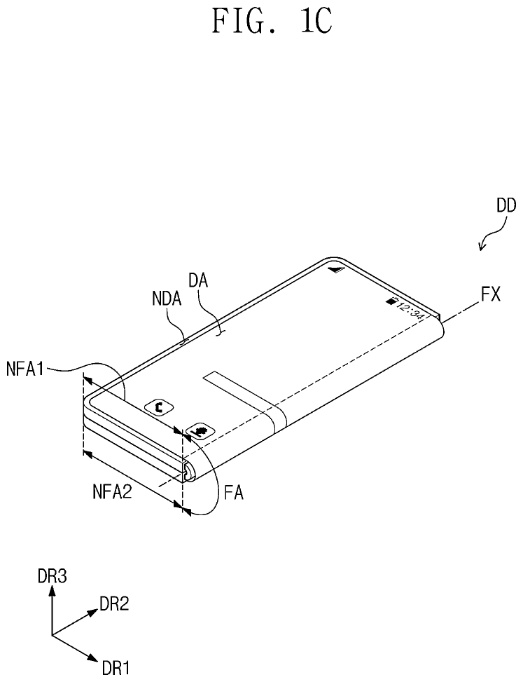

FIG. 1A is a perspective view of a display device DD according to one or more embodiments of the present disclosure. FIGS. 1B and 1C are perspective views illustrating a folded state of the display device DD illustrated in FIG. 1A.

The display device DD may be activated in response to an electrical signal, and may display an image. The display device DD may include various embodiments. For example, the display device DD may be not only a large-sized device, such as a television, or a billboard, but also may be a small-sized or medium-sized device, such as a monitor, a smartphone, a tablet computer, a navigation system, or a game console. These embodiments of the display device DD are examples, and are not limited to any one as long as not deviating from the concept of the present disclosure. A smartphone is illustrated as an example of the display device DD.

Referring to FIG. 1A, the display device DD may have, on a plane, a rectangular shape having short sides extending in a first direction DR1, and long sides extending in a second direction DR2 crossing the first direction DR1. However, the present disclosure is not limited thereto, and the display device DD may have, on a plane, various shapes, such as a circle, a polygon except for a rectangle, or the like.

The display device DD may be flexible. The wording “flexible” may mean a bendable property, and may include all ranging from a completely foldable structure to a bendable structure at the level of several nanometers. For example, the flexible display device DD may include a curved display device, a rollable display device, a slidable display device, or a foldable display device. A foldable display device is illustrated as an example of the flexible display device DD.

As illustrated in FIG. 1A, the display device DD in an unfolded state may display an image in a third direction DR3 through a display surface defined by the first direction DR1 and the second direction DR2. The third direction DR3 may be defined as a direction substantially perpendicularly crossing a surface defined by the first direction DR1 and the second direction DR2.

The front surface (or upper surface) and the rear surface (or lower surface) of each member constituting the display device DD may be opposed to each other in the third direction DR3, and the normal direction of each of the front surface and the rear surface may be substantially parallel to the third direction DR3. A distance between the front surface and the rear surface, and defined along the third direction DR3, may correspond to a thickness of the member (or unit).

In the present specification, the wording, “on a plane” may be defined as a state seen in the third direction DR3. In the present specification, the wording, “on a cross-section” may be defined as a state seen in the first direction DR1 or the second direction DR2. Meanwhile, directions indicated by the first to third directions DR1, DR2, and DR3 are relative concepts, and may be changed to other directions.

The front surface of the display device DD may be divided into a display region DA and a non-display region NDA. The display device DD may display an image through the display region DA, and a user may view the image through the display region DA. The image may include a static image as well as a dynamic image. FIG. 1A illustrates icons and a clock window as an example of the image.

The non-display region NDA may not display an image. The non-display region NDA may be adjacent to the display region DA. For example, the non-display region NDA may surround the display region DA on a plane/in plan view, but the present disclosure is not limited thereto. The non-display region NDA may be adjacent to only one side of the display region DA, or may be located in a side surface not the front surface of the display device DD. The non-display region NDA may correspond to a region in which a printing layer having a color (e.g., predetermined color) is formed, and may define a boundary of the display device DD.

The display region DA may include a sensing region TA. The sensing region TA may be a partial region of the display region DA. The sensing region TA may have a greater transmittance than any other region of the display region DA. Hereinafter, the other region of the display region DA except for the sensing region TA may be defined as a general display region.

An optical signal, such as visible light or infrared light, may move through the sensing region TA. An electronic device ED may capture an external image through the visible light penetrating the sensing region TA, or may determine, using the infrared light, whether or not an external object is near thereto. FIG. 1A illustrates one sensing region TA, but the present disclosure is not limited thereto, and the sensing region TA may be provided in plurality.

The display device DD may include a folding region FA, and non-folding regions NFA1 and NFA2. The non-folding regions NFA1 and NFA2 may include a first non-folding region NFA1, and a second non-folding region NFA2. The non-folding regions NFA1 and NFA2 may be arranged along the first direction DR1 with the folding region FA therebetween.

The folding region FA may be a region flat or bent with a curvature (e.g., predetermined curvature) according to a folding operation. As illustrated in FIG. 1A, when the display device DD is in a non-folding state, the folding region FA may be flat. The non-folding regions NFA1 and NFA2 may be regions maintaining flatness in both a folding state and a non-folding state.

The display device DD may be folded with respect to a folding axis extending along one direction. Referring to FIGS. 1B and 1C, a folding axis FX may extend along the second direction DR2 parallel to long sides of the display device DD. However, an extension direction of the folding axis FX is not limited thereto, and the folding axis FX may extend along a direction parallel to short sides of the display device DD. In this case, the non-folding regions may be arranged along the second direction DR2 with the folding region therebetween.

The display device DD may be in-folded or out-folded with respect to the folding axis FX. The display device DD may be folded to one state of being in-folded or being out-folded, or may be mutually changed from being in-folded to being out-folded. FIG. 1B illustrates the display device DD in an in-folded state, and FIG. 1C illustrates the display device DD in a completely out-folded state.

Referring to FIG. 1B, the folding axis FX according to one or more embodiments may be defined to face the front surface of the display device DD. A display surface corresponding to the folding region FA in the in-folded state may be folded facing the folding axis FX and may form a concavely curved surface. Display surfaces corresponding to the first and second non-folding regions NFA1 and NFA2 of the display device DD in the in-folded state may overlap each other facing each other. The front surface of the display device DD in the in-folded state may not be exposed to the outside.

Referring to FIG. 1C, the folding axis FX according to one or more embodiments may be defined to face the rear surface of the display device DD. A display surface corresponding to the folding region FA in the out-folded state may be folded opposed to the folding axis FX and may form a convexly curved surface. Display surfaces corresponding to the first and second non-folding regions NFA1 and NFA2 of the display device DD in the out-folded state may be exposed toward the outside. In the out-folded state, the display surfaces corresponding to the non-folding regions NFA1 and NFA2 may overlap each other on a plane, and may display an image in directions opposed to each other. The display region DA of the display device DD in the out-folded state may be exposed to the outside to display the image, and a user may view the image in the out-folded state.

The display device DD is illustrated as being in-folded or being out-folded with respect to one folding axis FX, but the number of the folding axis FX defined in the display device DD is not limited thereto, and the display device DD may be folded with respect to a plurality of folding axes. The folding operation of the display device DD is not limited to the illustrated embodiments, and may be designed in various forms.

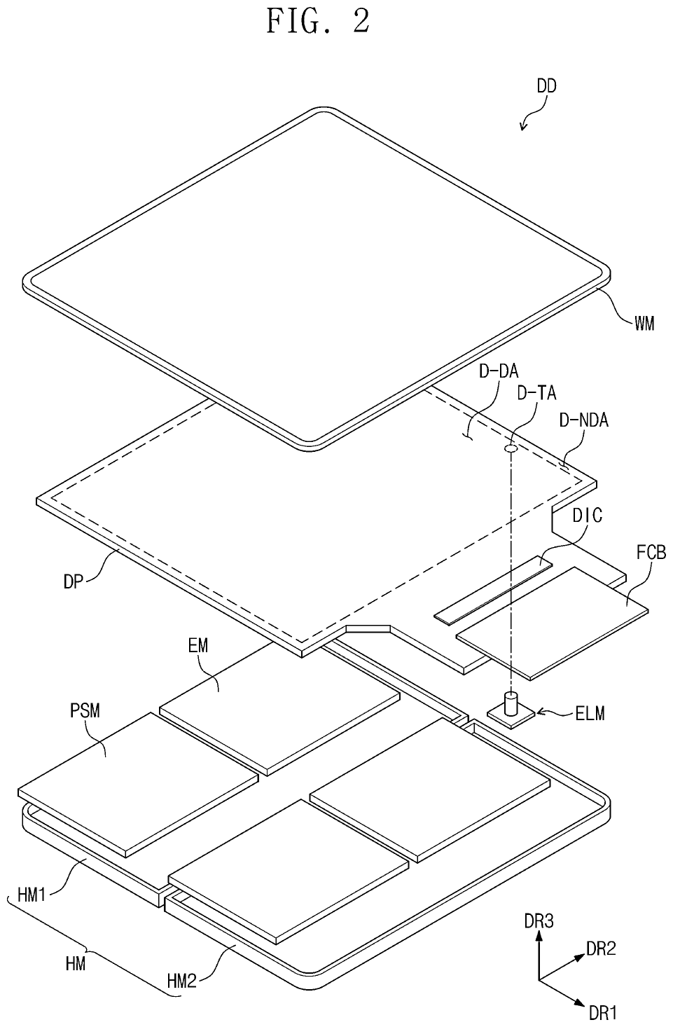

FIG. 2 is an exploded perspective view of a display device DD according to one or more embodiments of the present disclosure.

As illustrated in FIG. 2, the display device DD may include a window WM, a display panel DP, an electronic module EM, an electronic optical module ELM, a power supply module PSM, and a housing HM. In one or more embodiments, the display device DD may further include a mechanism structure for controlling a folding operation.

The display panel DP generates an image, and detects an external input. The window WM supplies the front surface of the display device DD. For example, the window WM may include a thin-film glass substrate. The window WM may include a bezel pattern defining the non-display region NDA described above. The window WM may further include a functional layer, such as a protective layer, a hard-coating layer, or an anti-fingerprint layer.

FIG. 2 illustrates only the display panel DP located under the window WM, but the display device DD may further include a plurality of configurations located on the display panel DP. For example, the display device DD may further include an input-sensing layer, or an anti-reflective layer.

The display panel DP is not particularly limited, and may be a light-emitting display panel, such as an organic light-emitting display panel, or a quantum dot light-emitting display panel. The display panel DP may include an ultra-small light-emitting element, such as a micro-LED or a nano-LED.

The display panel DP includes a display region D-DA and a non-display region D-NDA respectively corresponding to the display region DA (see FIG. 1A) and the non-display region NDA (see FIG. 1A) of the display device DD. In the present specification, the wording, “a region/portion corresponds to another region/portion” may mean “the region/portion overlaps the other region/portion,” and is not limited to that the two regions/portions have the same area.

The display panel DP may include a sensing region D-TA corresponding to the sensing region TA in FIG. 1A. The sensing region D-TA may have a lower resolution than the display region D-DA.

As illustrated in FIG. 2, a driving chip DIC may be located on the non-display region D-NDA of the display panel DP. A flexible circuit board FCB may be combined with the non-display region D-NDA of the display panel DP. The flexible circuit board FCB may be connected to a main circuit board. The main circuit board may be an electronic part constituting the electronic module EM.

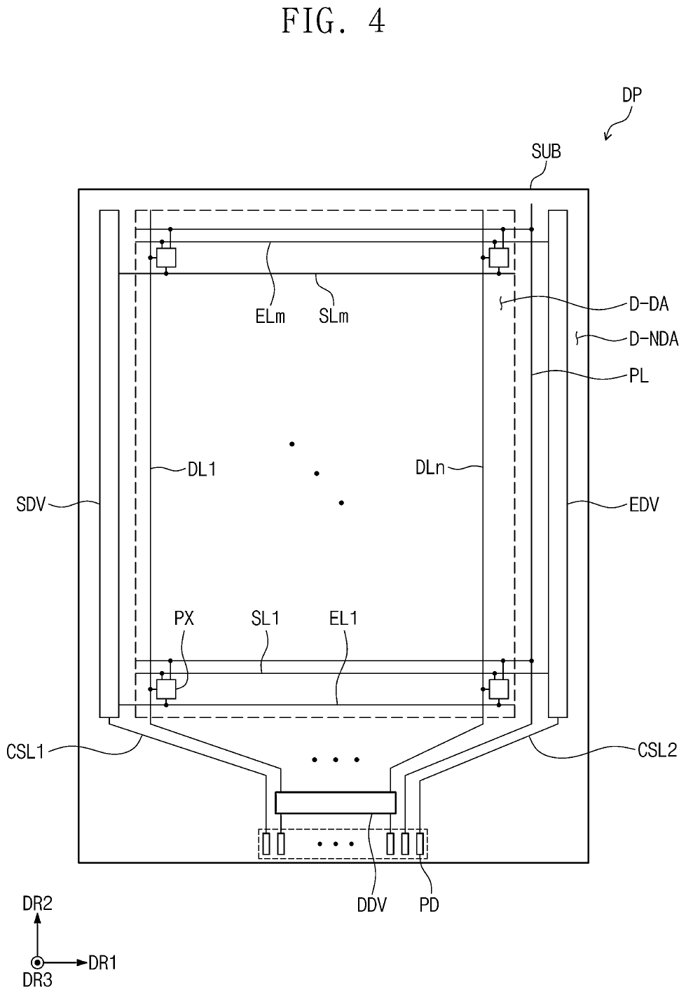

The driving chip DIC may include drivers for driving a pixel of the display panel DP, for example, a data driver DDV (see FIG. 4). FIG. 2 illustrates a structure in which the driving chip DIC is mounted on the display panel DP, but the present disclosure is not limited thereto. For example, the driving chip DIC may be mounted on the flexible circuit board FCB.

The power supply module PSM may supply power suitable for an overall operation of the display device DD. The power supply module PSM may include a general battery unit.

The electronic optical module ELM may be an electronic part that outputs or receives an optical signal. The electronic optical module ELM may include a camera module and/or a proximity sensor. The camera module captures an external image through the sensing region D-TA.

The housing HM illustrated in FIG. 2 may be combined with the display device DD, such as the window WM, to accommodate other modules described above. The housing HM is illustrated including first and second housings HM1 and HM2 separated from each other, but the present disclosure is not limited thereto. In one or more embodiments, the display device DD may further include a hinge structure for connecting the first and second housings HM1 and HM2.

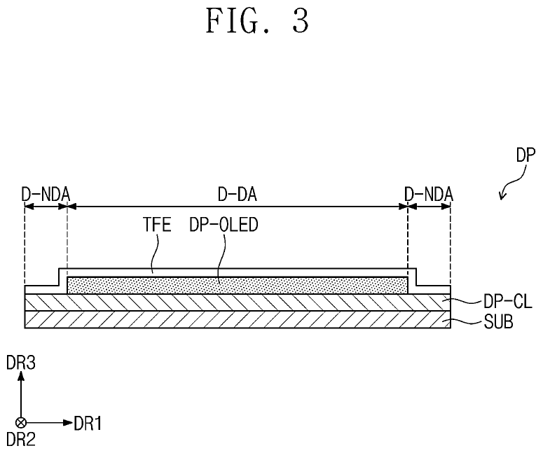

FIG. 3 is a cross-sectional view of a display panel DP according to one or more embodiments of the present disclosure.

The display panel DP may be included in the display device DD (see FIG. 1). The display panel DP according to one or more embodiments may be a light-emitting display panel, but is not limited thereto. For example, the display panel DP may be an organic light-emitting display panel, an inorganic light-emitting display panel, or a quantum dot light-emitting display panel. Hereinafter, the display panel DP will be described as an organic light-emitting display panel.

Referring to FIG. 3, the display panel DP may include a base layer SUB, a circuit element layer DP-CL, a display element layer DP-OLED, and an encapsulation layer TFE.

The base layer SUB may supply a base surface on which the circuit element layer DP-CL is located. The base layer SUB may include a display region D-DA and a non-display region D-NDA. The display region D-DA and the non-display region D-NDA of the base layer SUB may respectively correspond to the display region DA (see FIG. 1) and the non-display region NDA (see FIG. 1) of the display device DD (see FIG. 1).

The base layer SUB may include a flexible polymer material. For example, the base layer SUB may include at least one of an acrylic resin, a methacrylate-based resin, a polyisoprene-based resin, a vinyl-based resin, an epoxy-based resin, a urethane-based resin, a cellulose-based resin, a siloxane-based resin, a polyamide-based resin, a perylene-based resin, or a polyimide-based resin. However, a material of the base layer SUB is not limited to the above examples.

The circuit element layer DP-CL may be located on (as used herein, “located on” may mean “located above”) the base layer SUB. The circuit element layer DP-CL may include at least one insulating layer, a pixel circuit, signal lines, and signal pads to be described later. The circuit element layer DP-CL may be formed by patterning an insulating layer, a semiconductor layer, and a conductive layer through photolithography, after forming, on the base layer SUB, the insulating layer, the semiconductor layer, and the conductive layer through coating or deposition.

The display element layer DP-OLED may be located on the circuit element layer DP-CL. The display element layer DP-OLED may include light-emitting elements located overlapping the display region D-DA. The light-emitting elements of the display element layer DP-OLED may be electrically connected to the pixel circuit of the circuit element layer DP-CL, and may emit light through the display region DA in response to a driving signal.

The encapsulation layer TFE may be located on the display element layer DP-OLED to seal the light-emitting elements. The encapsulation layer TFE may include a plurality of thin-films. The thin-films of the encapsulation layer TFE may improve optical efficiency of the light-emitting elements, or may protect the light-emitting elements.

FIG. 4 is a plan view of a display panel DP according to one or more embodiments of the present disclosure.

Referring to FIG. 4, the display panel DP may include pixels PX located in a display region D-DA, and signal lines electrically connected to the pixels PX. The display panel DP may include a scan driver SDV, a data driver DDV, a light emission driver EDV, and signal pads PD located in a non-display region D-NDA.

Each of the pixels PX may include a light-emitting element, and a pixel circuit electrically connected to the light-emitting element, and including transistors (for example, a switching transistor, a driving transistor, and the like) and a capacitor. Each of the pixels PX may emit light in response to an electrical signal applied thereto.

The signal lines may include scanning lines SL1 to SLm, data lines DL1 to DLn, light-emitting lines EL1 to ELm, a first control line CSL1, a second control line CSL2, and a power line PL. Here, m and n are natural numbers of equal to or more than 1.

Each of the pixels PX may be connected to a corresponding scanning line of the scanning lines SL1 to SLm, to a corresponding data line of the data lines DL1 to DLn, and to a corresponding light-emitting line of the light-emitting lines EL1 to ELm. Meanwhile, the display panel DP may be provided with other types of signal lines according to configuration of the pixel circuit of the pixel PX.

The scan driver SDV and the light emission driver EDV may be each located in the non-display region D-NDA adjacent to long sides of the display panel DP. The data driver DDV may be located adjacent to a lower end of the display panel DP on a plane.

The scanning lines SL1 to SLm may extend in the first direction DR1 to be electrically connected to the scan driver SDV. The light-emitting lines EL1 to ELm may extend in the first direction DR1 to be electrically connected to the light emission driver EDV. The scanning lines SL1 to SLm and the light-emitting lines EL1 to ELm may be arranged along the second direction DR2. The data lines DL1 to DLn may cross the scanning lines SL1 to SLm and the light-emitting lines EL1 to ELm on a plane. The data lines DL1 to DLn may extend in the second direction DR2 to be electrically connected to the data driver DDV.

The power line PL may be electrically connected to the pixels PX to supply, to the pixels PX, a voltage applied to the power line PL. The power line PL may include a portion extending in the first direction DR1, and a portion extending in the second direction DR2. The portion of the power line PL extending in the first direction DR1 may extend on the display region D-DA to be connected to the pixels PX, and the portion of the power line PL extending in the second direction DR2 may extend on the non-display region D-NDA to be connected to the signal pad PD. The portion of the power line PL extending in the first direction DR1, and the portion of the power line PL extending in the second direction DR2, may be connected on a different layer through a contact hole, or may have an integrated shape on the same layer.

The first control line CSL1 may be electrically connected to the scan driver SDV. The second control line CSL2 may be electrically connected to the light emission driver EDV.

The signal pads PD may be arranged along the first direction DR1. The signal pads PD may be electrically connected to a circuit board, and the circuit board may include a timing controller for controlling operations of the scan driver SDV, the data driver DDV, and the light emission driver EDV, and a voltage generator for generating voltages suitable for driving the display panel DP.

The signal pads PD may be respectively connected to corresponding signal lines. For example, the first control line CSL1, the second control line CSL2, the power line PL, and the data lines DL1 to DLn may be respectively connected to the signal pads PD. The data lines DL1 to DLn may be respectively electrically connected to corresponding signal pads PD through the data driver DDV.

The scan driver SDV may generate scanning signals in response to scanning control signals. The scanning signals may be applied to the pixels PX through the scanning lines SL1 to SLm. The data driver DDV may generate data voltages corresponding to image signals in response to data control signals. The data voltages may be applied to the pixels PX through the data lines DL1 to DLn. The light emission driver EDV may generate light-emitting signals in response to light-emitting control signals. The light-emitting signals may be applied to the pixels PX through the light-emitting lines EL1 to ELm.

The pixels PX may be supplied with the data voltages in response to the scanning signals. The pixels PX may display an image by emitting light having luminance corresponding to the data voltages in response to the light-emitting signals. A light-emitting time of the pixels PX may be controlled by the light-emitting signals. As a result, the display panel DP may output the image on the display region D-DA through the pixels PX.

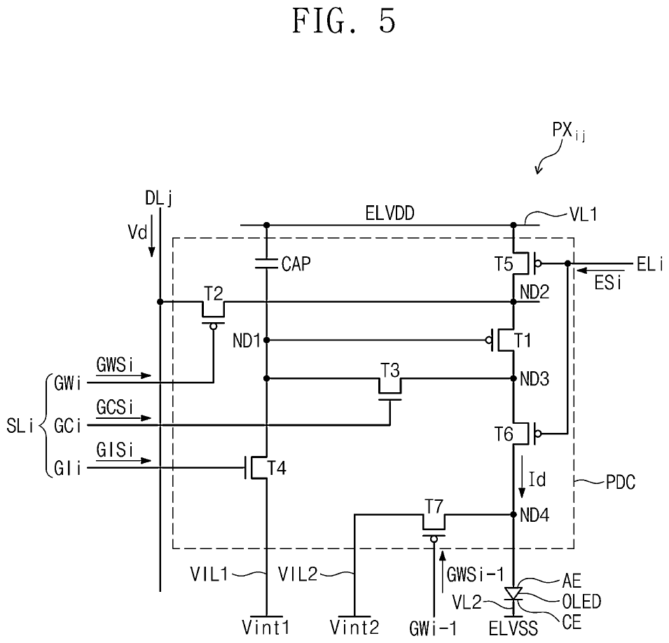

FIG. 5 is a diagram illustrating an equivalent circuit of a pixel PXij according to one or more embodiments of the present disclosure. FIG. 5 illustrates the pixel PXij connected to an i-th scanning line SLi, an i-th light-emitting line ELi, and a j-th data line DLj. Here, i and j are natural numbers.

Referring to FIG. 5, the pixel PXij may include a light-emitting element OLED and a pixel circuit PDC electrically connected to the light-emitting element OLED. The pixel circuit PDC may include transistors T1, T2, T3, T4, T5, T6, and T7 and a capacitor CAP. The transistors T1, T2, T3, T4, T5, T6, and T7 and the capacitor CAP may control an amount of current flowing the light-emitting element OLED, and the light-emitting element OLED may generate light having a luminance (e.g., predetermined luminance) depending on the amount of current supplied thereto.

The i-th scanning line SLi may include i-th first to third scanning lines GWi, GCi, and GIi. A first scanning line GWi that receives an i-th writing scanning signal GWSi may be defined as a writing scanning line GWi. A second scanning line GCi that receives an i-th compensation scanning signal GCSi may be defined as a compensation scanning line GCi. A third scanning line GIi that receives an i-th initialization scanning signal GISi may be defined as an initialization scanning line GIi.

The transistors T1, T2, T3, T4, T5, T6, and T7 may include first to seventh transistors T1, T2, T3, T4, T5, T6, and T7. The first to seventh transistors T1, T2, T3, T4, T5, T6, and T7 may each include a source electrode, a drain electrode, and a gate electrode. Hereinafter, the source electrode may be referred to as a source, the drain electrode may be referred to as a drain, and the gate electrode may be referred to as a gate.

Meanwhile, in the present specification, the wording, “a transistor and a signal line, or a transistor and another transistor are electrically connected” means “an electrode of the transistor and the signal line, or an electrode of the transistor and an electrode of the other transistor have an integrated shape, or are connected through a connection electrode.”

The first to seventh transistors T1, T2, T3, T4, T5, T6, and T7 may have an oxide semiconductor layer, or a low-temperature polycrystalline silicon (LTPS) semiconductor layer. The first to seventh transistors T1, T2, T3, T4, T5, T6, and T7 may be an N-type transistor or a P-type transistor. For example, first, second, fifth, sixth, and seventh transistors T1, T2, T5, T6, and T7 may be PMOS transistors having the LTPS semiconductor layer, and third and fourth transistors T3 and T4 may be NMOS transistors having the oxide semiconductor layer. However, embodiments of the transistors T1, T2, T3, T4, T5, T6, and T7 are not limited thereto. In addition, the pixel circuit PDC including the seven transistors T1, T2, T3, T4, T5, T6, and T7 is illustrated, but the number of transistors included in the pixel circuit PDC is not limited thereto.

The light-emitting element OLED may be defined as an organic light-emitting element. The light-emitting element OLED may include a first electrode AE and a second electrode CE. For example, the first electrode AE may be an anode, and the second electrode CE may be a cathode. The first electrode AE of the light-emitting element OLED may be electrically connected to a first voltage line VL1 that receives a first driving voltage ELVDD. The second electrode CE of the light-emitting element OLED may be electrically connected to a second voltage line VL2 that receives a second driving voltage ELVSS.

The first transistor T1 may electrically connect the first voltage line VL1 that receives the first driving voltage ELVDD, and the light-emitting element OLED. The first transistor T1 may include a source connected to a second node ND2, a drain connected to a third node ND3, and a gate connected to a first node ND1. The first transistor T1 may be turned on by a voltage of the first node ND1. The first transistor T1 may receive a data voltage Vd transmitted by a data line DLj to supply a driving current Id to the light-emitting element OLED, according to a switching operation of the second transistor T2. The first transistor T1 may be defined as a driving transistor.

The second transistor T2 may electrically connect the data line DLj and the first transistor T1. The second transistor T2 may include a source connected to the data line DLj, a drain connected to the second node ND2, and a gate connected to the first scanning line GWi. The first transistor T1 and the second transistor T2 may be connected through the second node ND2. The second transistor T2 may be turned on by the writing scanning signal GWSi applied through the first scanning line GWi. The second transistor T2 turned on may transmit the data voltage Vd applied to the data line DLj to the source of the first transistor T1. The second transistor T2 may be defined as a switching transistor.

The third transistor T3 may electrically connect the first transistor T1 and the fourth transistor T4. The third transistor T3 may include a source connected to the first node ND1, a drain connected to the third node ND3, and a gate connected to the second scanning line GCi. The first transistor T1 and the third transistor T3 may be connected through the third node ND3. The third transistor T3 may be turned on by the compensation scanning signal GCSi applied through the second scanning line GCi. The third transistor T3 turned on may electrically connect the gate of the first transistor T1 and the drain of the first transistor T1 to connect the first transistor T1 in the form of a diode. The third transistor T3 may be defined as a compensation transistor.

The fourth transistor T4 may electrically connect a first initialization line VIL1 that receives a first initialization voltage Vint1 and the third transistor T3. The fourth transistor T4 may include a source connected to the first initialization line VIL1, a drain connected to the first node ND1, and a gate connected to the third scanning line GIi. The fourth transistor T4 may be turned on by the initialization scanning signal GISi applied through the third scanning line GIi. The fourth transistor T4 turned on may transmit the first initialization voltage Vint1 to the first node ND1, and may initialize a gate voltage of the first transistor T1. The fourth transistor T4 may be defined as an initialization transistor.

The fifth transistor T5 may electrically connect the first voltage line VL1 that receives a first driving voltage ELVDD and the first transistor T1. The fifth transistor T5 may include a source connected to the first voltage line VL1, a drain connected to the second node ND2, and a gate connected to the light-emitting line ELi.

The sixth transistor T6 may electrically connect the first transistor T1 and the light-emitting element OLED. The sixth transistor T6 may include a source connected to the third node ND3, a drain connected to the first electrode AE of the light-emitting element OLED through a fourth node ND4, and a gate connected to the light-emitting line ELi.

The fifth transistor T5 and the sixth transistor T6 may be turned on by the light-emitting signal ESi applied through the light-emitting line ELi. A light-emitting time of the light-emitting element OLED may be controlled by the light-emitting signal ESi. When the fifth transistor T5 and the sixth transistor T6 are turned on, a driving current Id according to a voltage difference between a gate voltage of the gate of the first transistor T1 and the first driving voltage ELVDD may be generated, and may be supplied to the light-emitting element OLED through the sixth transistor T6 so that the light-emitting element OLED may emit light. The fifth transistor T5 and the sixth transistor T6 may be defined as light-emission control transistors.

The seventh transistor T7 may electrically connect the sixth transistor T6 and a second initialization line VIL2 that receives a second initialization voltage Vint2. The seventh transistor T7 may include a source connected to the fourth node ND4, a drain connected to the second initialization line VIL2, and a gate connected to a first scanning line GWi-1. The gate of the seventh transistor T7 may be connected to an (i−1)-th writing scanning line GWi-1, which is a writing scanning line that precedes the i-th writing scanning line GWi. However, the present disclosure is not limited thereto, and the gate of the seventh transistor T7 may be electrically connected to a separate fourth scanning line.

The seventh transistor T7 may be turned on by an (i−1)-th writing scanning signal GWSi-1 applied through the first scanning line GWi-1. The turned-on seventh transistor T7 may transmit the second initialization voltage Vint2 to the fourth node ND4. The second initialization voltage Vint2 may have the same level as the first initialization voltage Vint1, but the present disclosure is not limited thereto, and the second initialization voltage Vint2 may have a level that is different from the first initialization voltage Vint1. The seventh transistor T7 may be defined as an initialization transistor.

The seventh transistor T7 may improve black expression ability of the pixel PXij. The driving current Id may partially flow out through the seventh transistor T7 as a bypath current. When a black image is displayed, current reduced from the driving current Id by an amount of the bypath current flowing out through the seventh transistor T7 may be supplied to the light-emitting element OLED to clearly express the black image. That is, an accurate black luminance image may be performed through the seventh transistor T7, thereby improving a contrast ratio of the display device DD (see FIG. 1).

The capacitor CAP may include a first electrode that receives the first driving voltage ELVDD, and a second electrode connected to the first node ND1. A charge corresponding to a voltage difference between the first electrode and the second electrode may be stored in the capacitor CAP. When the fifth transistor T5 and the sixth transistor T6 are turned on, an amount of current flowing in the first transistor T1 may be determined according to the voltage stored in the capacitor CAP.

Meanwhile, the configuration of the pixel circuit PDC illustrated in FIG. 5 is an example, and the configuration of the pixel circuit PDC is not limited thereto, and may be changed.

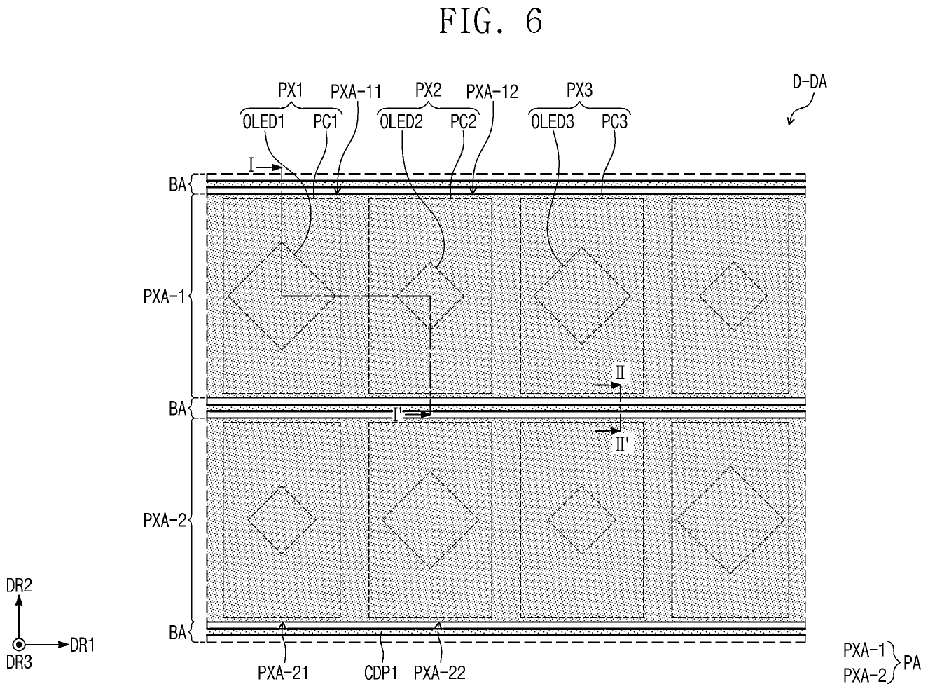

FIG. 6 is an enlarged plan view of a display panel DP according to one or more embodiments of the present disclosure. FIG. 6 partially briefly illustrates a display region D-DA of the display panel DP.

The display region D-DA includes a plurality of pixel regions PA and a boundary region BA between the plurality of pixel regions PA. The pixel regions PA may include a plurality of pixel rows PXA-1 and PXA-2 extending in the first direction DR1, and the boundary region BA may be located between the pixel rows PXA-1 and PXA-2.

Two pixel rows PXA-1 and PXA-2 are illustrated in FIG. 6. The first pixel row PXA-1 may include a first color pixel PX1, a second color pixel PX2, a third color pixel PX3, and another second color pixel PX2 arranged in the first direction DR1. The second pixel row PXA-2 may include a second color pixel PX2, a third color pixel PX3, another second color pixel PX2, and a first color pixel PX1. Four color pixels of the pixel rows PXA-1 and PXA-2 illustrated in FIG. 6 may be repeatedly located along the first direction DR1. Color pixels of the pixel rows PXA-1 and PXA-2 illustrated in FIG. 6 may be repeatedly located along the second direction DR2. Meanwhile, in the present specification, the first pixel row PXA-1 may be described as “a first pixel region,” and the second pixel row PXA-2 may be described as “a second pixel region.”

Pixel circuits PC1, PC2, and PC3 of the first color pixel PX1, the second color pixel PX2, and the third color pixel PX3 may be respectively located in the plurality of pixel regions PA. Each of the pixel circuits PC1, PC2, and PC3 may be the same as the pixel circuit PDC described with reference to FIG. 5. FIG. 6 illustrates that each of the pixel circuits PC1, PC2, and PC3 is substantially the same as the pixel regions PA, but the present disclosure is not limited thereto.

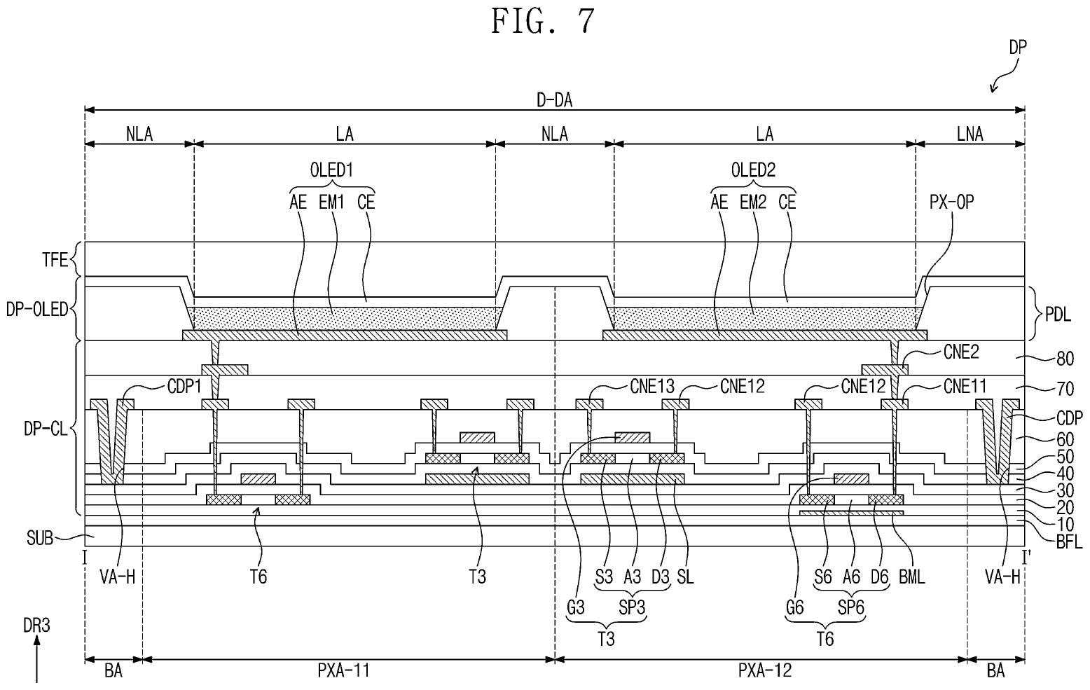

The pixel region PA may be defined as a region except for the boundary region BA in the display region D-DA. The boundary region BA may be defined by a valley hole VA-H (see FIG. 7) to be described later, and the display region D-DA not overlapping the valley hole VA-H may correspond to the pixel region PA. It is illustrated that any one of the first color pixel PX1, the second color pixel PX2, and the third color pixel PX3 is located in each of the pixel regions PA, but a plurality of color pixels may be located in one pixel region PA.

A first light-emitting element OLED1, a second light-emitting element OLED2, and a third light-emitting element OLED3 may be respectively located in the plurality of pixel regions PA. FIG. 6 illustrates anodes, indicated by dotted lines, respectively representing the first light-emitting element OLED1, the second light-emitting element OLED2, and the third light-emitting element OLED3.

FIG. 6 illustrates a light-emitting element and a pixel circuit included in each of the first pixel region PXA-1 and the second pixel region PXA-2, and does not illustrate signal lines, such as the scanning lines SL1 to SLm, the data lines DL1 to DLn, the light-emitting lines EL1 to ELm, the first control line CSL1, and the second control line CSL2, etc., illustrated in FIG. 4.

FIG. 6 illustrates a first conductive pattern CDP1. The first conductive pattern CDP1 overlaps the boundary region BA. The first conductive pattern CDP1 may be located overlapping the valley hole VA-H (see FIG. 7) to be described later. The first conductive pattern CDP1 substantially extends in the same direction as the boundary region BA. That is, the first conductive pattern CDP1 may extend in the first direction DR1.

The boundary region BA may extend in the first direction DR1, and may not extend in the second direction DR2. The boundary region BA may extend in the first direction DR1 to overlap/to be aligned with, in the second direction DR2, a plurality of pixel regions PA arranged in the first direction DR1. In one or more embodiments, the first pixel region PXA-1 may include a (1-1)-th pixel region PXA-11 and a (1-2)-th pixel region PXA-12 arranged along the first direction DR1, and the boundary region BA may overlap each of the (1-1)-th pixel region PXA-11 and the (1-2)-th pixel region PXA-12 in the second direction DR2. The second pixel region PXA-2 may include a (2-1)-th pixel region PXA-21 and a (2-2)-th pixel region PXA-22 arranged along the first direction DR1, and the boundary region BA may overlap each of the (2-1)-th pixel region PXA-21 and the (2-2)-th pixel region PXA-22 in the second direction DR2.

In the display panel DP according to one or more embodiments, the boundary region BA included in the display region D-DA may not extend in the second direction DR2 not to overlap each of the pixel rows PXA-1 and PXA-2 in the first direction DR1. That is, the boundary region BA may not be located between the plurality of pixel regions included in each of the pixel rows PXA-1 and PXA-2. In one or more embodiments, because the boundary region BA is not located between the (1-1)-th pixel region PXA-11 and the (1-2)-th pixel region PXA-12, the (1-1)-th pixel region PXA-11 and the (1-2)-th pixel region PXA-12 may be successively arranged along the first direction DR1. Because the boundary region BA is not located between the (2-1)-th pixel region PXA-21 and the (2-2)-th pixel region PXA-22, the (2-1)-th pixel region PXA-21 and the (2-2)-th pixel region PXA-22 may be successively arranged along the first direction DR1.

The first conductive pattern CDP1 may entirely overlap the boundary region BA. The first conductive pattern CDP1 may be entirely located the boundary region BA extending along the first direction DR1. The first conductive pattern CDP1 may extend in the first direction DR1 to overlap/to be aligned with, in the second direction DR2, the plurality of pixel regions PA arranged in the first direction DR1. The first conductive pattern CDP1 may entirely cover the valley hole VA-H (see FIG. 7) to be described later.

The first conductive pattern CDP1 may not extend in the second direction DR2, like the boundary region BA. The boundary region BA may not extend in the second direction DR2 in the display panel DP according to one or more embodiments, thereby allowing higher resolution due to a small decrease in resolution due to the valley hole VA-H (see FIG. 7). The first conductive pattern CDP1 may not extend in the second direction DR2, thereby reducing or preventing the likelihood of a limitation that signal lines extending in the first direction DR1 overlap the first conductive pattern CDP1.

FIG. 7 is a cross-sectional view of a display panel DP according to one or more embodiments of the present disclosure. FIG. 7 illustrates a cross-section taken along the line I-I′ in FIG. 6. FIG. 7 illustrates light-emitting elements OLED1 and OLED2, and some transistors T3 and T6 of the pixel circuits PDC (see FIG. 5) that are respectively connected to the light-emitting elements OLED1 and OLED2. Description made above may be applied to configurations of the display panel DP illustrated in FIG. 7.

Referring to FIG. 7, the display panel DP may include a base layer SUB, a circuit element layer DP-CL, a display element layer DP-OLED, and an encapsulation layer TFE.

The base layer SUB may supply a base surface on which a circuit element layer DP-CL is located. The circuit element layer DP-CL may include insulating layers BFL, 10, 20, 30, 40, 50, 60, 70, and 80, transistors T3 and T6, and connection electrodes CNE11, CNE12, CNE13, and CNE2. The insulating layers BFL, 10, 20, 30, 40, 50, 60, 70, and 80 may include a buffer layer BFL, and first to eighth insulating layers 10, 20, 30, 40, 50, 60, 70, and 80 located on the buffer layer BFL. However, insulating layers included in the circuit element layer DP-CL are not limited thereto, and may be changed according to configuration of a pixel circuit included in the circuit element layer DP-CL, and a process of manufacturing the circuit element layer DP-CL.

The buffer layer BFL may be located on the base layer SUB. The buffer layer BFL may include at least one inorganic layer. For example, the buffer layer BFL may include at least one of aluminum oxide, titanium oxide, silicon oxide, silicon nitride, silicon oxynitride, zirconium oxide, or hafnium oxide. The buffer layer BFL may improve an adhesive force between a semiconductor layer (for example, a sixth semiconductor pattern SP6) or a conductive pattern layer of the circuit element layer DP-CL located on the base layer SUB, and the base layer SUB.

The first to eighth insulating layers 10, 20, 30, 40, 50, 60, 70, and 80 may each include an inorganic layer and/or an organic layer, and may have a single-layered or multi-layered structure. The inorganic layer may include at least one of aluminum oxide, titanium oxide, silicon oxide, silicon nitride, silicon oxynitride, zirconium oxide, or hafnium oxide, but a material of the inorganic layer is not limited thereto. The organic layer may include at least any one of an acrylic resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. However, a material of the organic layer is not limited thereto.

A blocking pattern BML may be located on the buffer layer BFL. When the buffer layer BFL is omitted, the blocking pattern BML may be directly located on the base layer SUB. The blocking pattern BML may include molybdenum. The blocking pattern BML may have a shielding function. The blocking pattern BML may block electric potential due to a polarization phenomenon between the first to eighth insulating layers 10, 20, 30, 40, 50, 60, 70, and 80 located on the blocking pattern BML from affecting transistors T1, T2, T3, T4, T5, T6, and T7 (see FIG. 5).

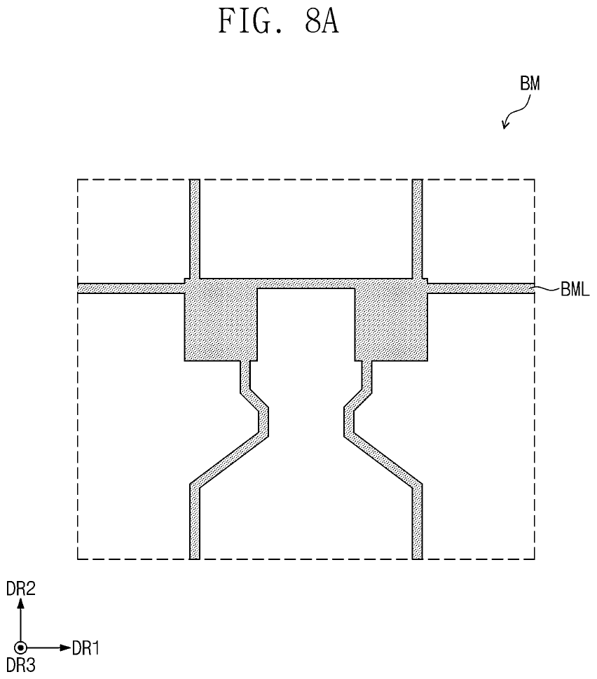

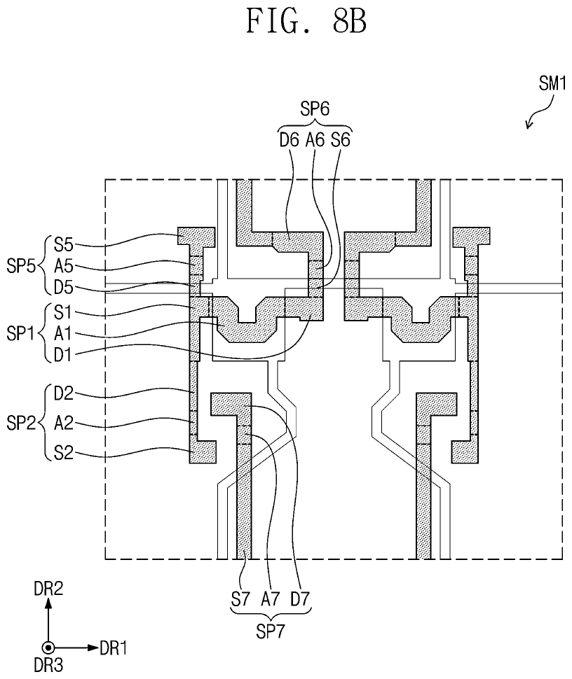

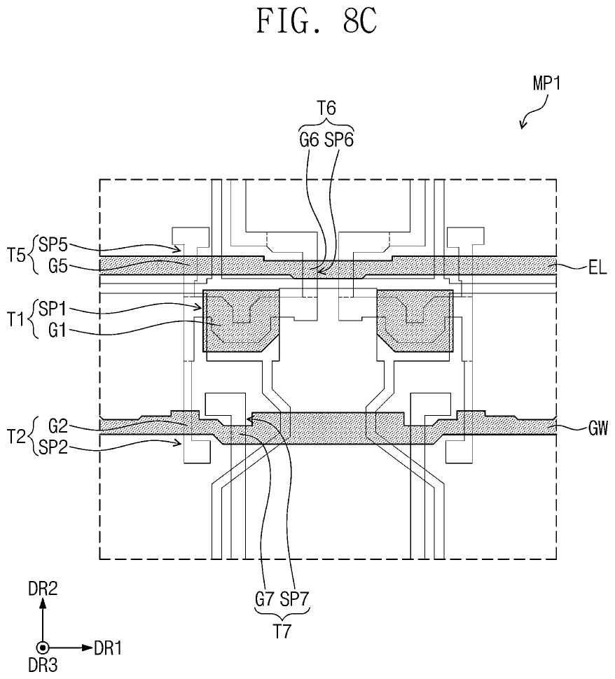

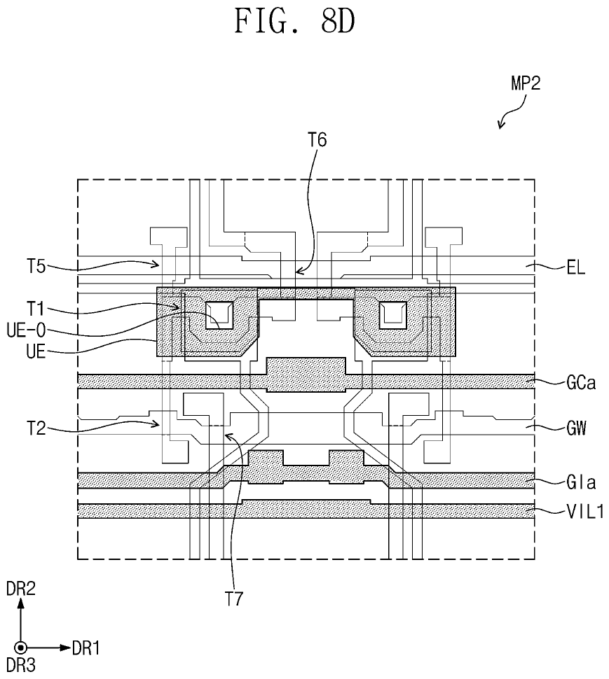

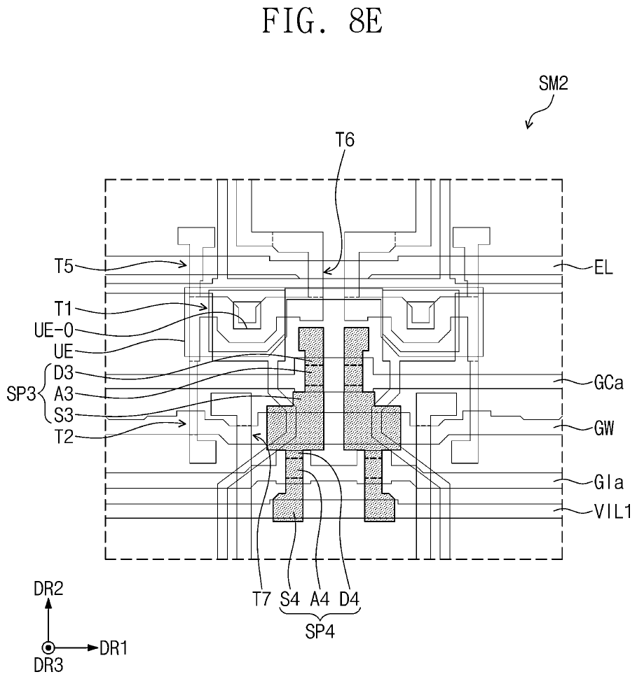

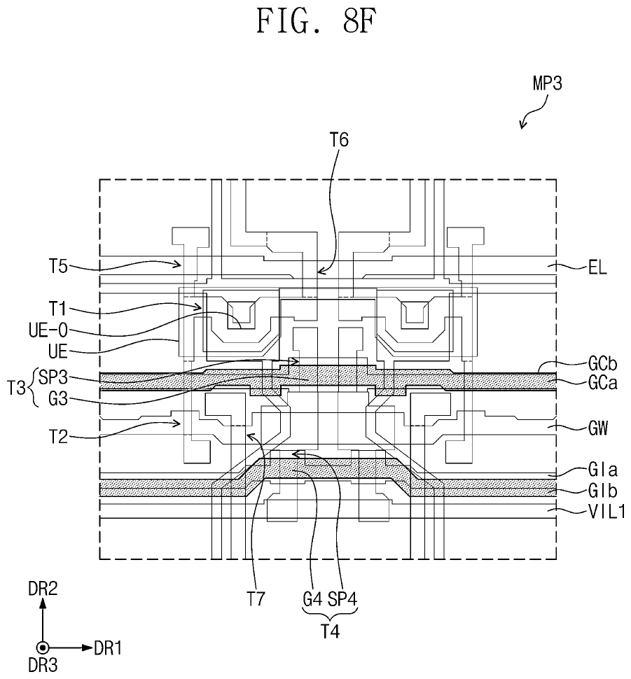

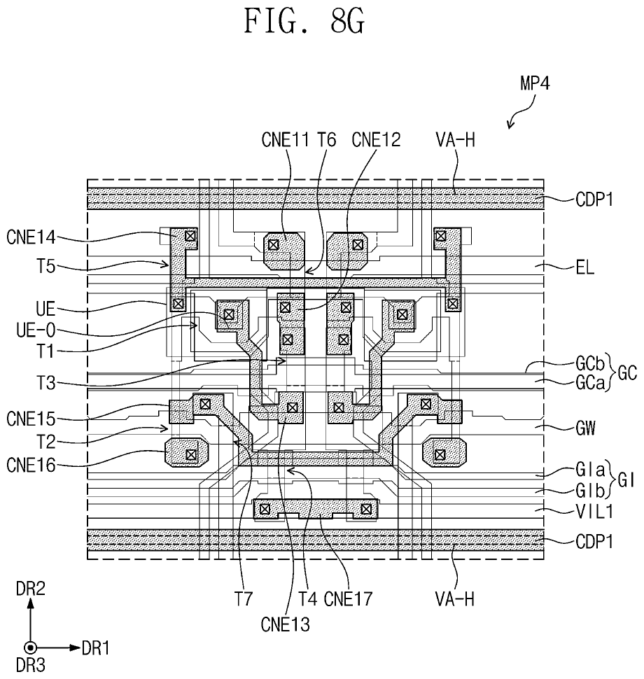

A first semiconductor pattern layer SM1 (see FIG. 8B) may be located on the first insulating layer 10. The first semiconductor pattern layer may include silicon semiconductor. For example, the first semiconductor pattern layer may include polycrystalline silicon or amorphous silicon. However, a material included in the first semiconductor pattern layer is not limited thereto as long as the first semiconductor pattern layer has a semiconductor property.

The first semiconductor pattern layer may include a plurality of regions having different respective electrical properties according to whether or not the plurality of regions are doped. The first semiconductor pattern layer may include a first region having a high conductivity and a second region having a low conductivity. The first region may be doped with a N-type dopant or a P-type dopant. A P-type transistor may include a doped region doped with the P-type dopant, and an N-type transistor may include a doped region doped with the N-type dopant. The second region may be an undoped region, or a region doped at a lower concentration than the first region.

The first region may have a higher conductivity than the second region, and may substantially serve as a source and a drain of a transistor. The second region may substantially correspond to a channel (or channel region, or active layer) of the transistor. That is, of the first semiconductor pattern layer, the first region having a higher conductivity may be a source, a drain, or a connection signal line of the transistor, and the second region having a lower conductivity may be a channel of the transistor.

The sixth semiconductor pattern SP6 of the sixth transistor T6 may be formed from the first semiconductor pattern layer. The sixth semiconductor pattern SP6 may include a sixth source S6, a sixth channel A6, and a sixth drain D6. The sixth source S6 and the sixth drain D6 may respectively extend from the sixth channel A6 in directions opposed to each other. That is, the sixth source S6 and the sixth drain D6 may be spaced apart from each other on a plane with the sixth channel A6 therebetween.

The first insulating layer 10 may be located on the buffer layer BFL. The first insulating layer 10 may cover the blocking pattern BML. The second insulating layer 20 may be located on the first insulating layer 10. The second insulating layer 20 may cover the first semiconductor pattern layer. For example, the second insulating layer 20 may cover the sixth semiconductor pattern SP6.

A first conductive pattern layer MP1 (see FIG. 8C) may be located on the first insulating layer 10. A sixth gate electrode G6 may be formed from the first conductive pattern layer, and the sixth gate electrode G6 may be located on the second insulating layer 20. The sixth gate electrode G6 may overlap the sixth channel A6. In one or more embodiments, the sixth gate electrode G6 may function as a mask in a process of doping the sixth semiconductor pattern SP6.

FIG. 7 illustrates that the sixth transistor T6 has a top-gate structure in which the sixth gate electrode G6 is located on the sixth semiconductor pattern SP6, but the present disclosure is not limited thereto, and the sixth transistor T6 may have a bottom-gate structure in which the sixth gate electrode G6 of the sixth transistor T6 is located under the sixth semiconductor pattern SP6.

Meanwhile, first, second, fifth, and seventh transistors T1, T2, T5, and T7 (see FIG. 5) described above may be transistors having the same structure as the sixth transistor T6. For example, semiconductor patterns of the first, second, fifth, and seventh transistors T1, T2, T5, and T7 may be formed from the first semiconductor pattern layer like the sixth semiconductor pattern SP6, and gate electrodes of the first, second, fifth, and seventh transistors T1, T2, T5, and T7 may be formed from the first conductive pattern layer like the sixth gate electrode G6, but one or more embodiments of the present disclosure is not necessarily limited thereto.

The third insulating layer 30 may be located on the second insulating layer 20. The third insulating layer 30 may cover the first conductive pattern layer. For example, the third insulating layer 30 may cover the sixth gate electrode G6.

A second conductive pattern layer MP2 (see FIG. 8D) may be located on the third insulating layer 30. The second conductive pattern layer may include a scanning line SL. In one or more embodiments, the second conductive pattern layer may further include an upper electrode UE (see FIG. 8D). The scanning line SL may partially correspond to the first to third scanning lines GWi, GCi, and Gli (see FIG. 5) described above.

The fourth insulating layer 40 may be located on the third insulating layer 30. The fourth insulating layer 40 may cover the second conductive pattern layer. For example, the fourth insulating layer 40 may cover the scanning line SL.

A second semiconductor pattern layer may be located on the fourth insulating layer 40. The second semiconductor pattern layer may include a semiconductor material different from the first semiconductor pattern layer. For example, the second semiconductor pattern layer may include an oxide semiconductor including a metal oxide. The oxide semiconductor may include an oxide of metal, such as zinc (Zn), indium (In), gallium (Ga), tin (Sn), or titanium (Ti), or a mixture of metal, such as zinc (Zn), indium (In), gallium (Ga), tin (Sn), or titanium (Ti) and/or an oxide thereof. The oxide semiconductor may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), zinc-tin oxide (ZTO), or the like, but one or more embodiments of the present disclosure is not necessarily limited thereto.

The second semiconductor pattern layer may include a plurality of regions having electrical properties different according to whether or not the metal oxide is reduced. A region (hereinafter, a reduction region) in which the metal oxide of the second semiconductor pattern layer is reduced, may have a greater conductivity than a region (hereinafter, a non-reduction region) in which the metal oxide of the second semiconductor pattern layer is not reduced. The reduction region may substantially serve as a source or a drain of the transistor. The non-reduction region may substantially serve as a channel (or active region) of the transistor.

The third semiconductor pattern SP3 of the third transistor T3 may be formed from the second semiconductor pattern layer. The third semiconductor pattern SP3 may include a third source S3, a third channel A3, and a third drain D3. The third source S3 and the third drain D3 may respectively extend from the third channel A3 in directions opposed to each other. That is, the third source S3 and the third drain D3 may be spaced apart from each other on a plane with the third channel A3 therebetween.

The fifth insulating layer 50 may be located on the fourth insulating layer 40. The fifth insulating layer 50 may cover the second semiconductor pattern layer. For example, the fifth insulating layer 50 may cover the third semiconductor pattern SP3.

A third conductive pattern layer MP3 (see FIG. 8F) may be located on the fifth insulating layer 50. The third gate electrode G3 may be formed from the third conductive pattern layer, and the third gate electrode G3 may be located on the fifth insulating layer 50. The third gate electrode G3 may overlap the third channel A3. In one or more embodiments, the third gate electrode G3 may function as a mask in a process of doping the third semiconductor pattern SP3.

The third semiconductor pattern SP3 may partially overlap the scanning line SL located under the third semiconductor pattern SP3. A portion of the scanning line SL overlapping the third semiconductor pattern SP3 may serve as a gate of the third transistor T3 with the third gate electrode G3. In this case, a third gate of the third transistor T3 may be doubly formed to have a sufficient gate charge, and may be switched at a high speed. In addition, the scanning line SL may be located overlapping the third semiconductor pattern SP3, thereby reducing or preventing the likelihood of the third semiconductor pattern SP3 being damaged by light introduced from the lower portion of the display panel DP. However, this structure of the third transistor T3 is an example, and the present disclosure is not limited thereto.

Meanwhile, the fourth transistor T4 (see FIG. 5) described above may have the same structure as the third transistor T3. For example, a semiconductor pattern of the fourth transistor T4 may be formed from the second semiconductor pattern layer like the third semiconductor pattern SP3, and a gate electrode of the fourth transistor T4 may be formed from the third conductive pattern layer like the third gate electrode G3, but one or more embodiments of the present disclosure is not necessarily limited thereto.

The third semiconductor pattern SP3 of the third transistor T3 and the sixth semiconductor pattern SP6 of the sixth transistor T6 may be located on different layers. However, this is an example, and semiconductor patterns of all transistors included in the pixel circuit PDC (see FIG. 5) may be located on the same layer.

The sixth insulating layer 60 may be located on the fifth insulating layer 50. The sixth insulating layer 60 may cover the third conductive pattern layer. For example, the sixth insulating layer 60 may cover the third gate electrode G3. Meanwhile, in the present specification, the first to sixth insulating layers 10, 20, 30, 40, 50, and 60 may be described as “a plurality of lower insulating layers.”

A fourth conductive pattern layer MP4 (see FIG. 8G) may be located on the sixth insulating layer 60. Connection electrodes CNE11, CNE12, and CNE13 may be formed from the fourth conductive pattern layer. The first conductive pattern CDP1 may be formed from the fourth conductive pattern layer. The connection electrodes CNE11, CNE12, and CNE13 may include (1-1)-th to (1-3)-th connection electrodes CNE11, CNE12, and CNE13. The (1-1)-th to (1-3)-th connection electrodes CNE11, CNE12, and CNE13 and the first conductive pattern CDP1 may be spaced apart from each other on the same layer. Meanwhile, in the present specification, the sixth insulating layer 60, which is a base insulating layer on which the fourth conductive pattern layer is located, may be described as “a first reference insulating layer,” and the fifth insulating layer 50 located under the sixth insulating layer 60 may be described as “a second reference insulating layer.”

The (1-1)-th connection electrode CNE11 may be connected to the sixth drain D6 of the sixth transistor T6. The (1-1)-th connection electrode CNE11 may be connected to the sixth drain D6 through a contact hole penetrating the second to sixth insulating layers 20, 30, 40, 50, and 60.

The (1-2)-th connection electrode CNE12 may be connected to the sixth source S6 of the sixth transistor T6. The (1-2)-th connection electrode CNE12 may be connected to the sixth source S6 through a contact hole penetrating the second to sixth insulating layers 20, 30, 40, 50, and 60.

The (1-2)-th connection electrode CNE12 may extend on a plane to overlap the third drain D3 of the third transistor T3. The (1-2)-th connection electrode CNE12 may be connected to the third drain D3 through a contact hole penetrating the fifth and sixth insulating layers 50 and 60. Accordingly, the third semiconductor pattern SP3 of the third transistor T3 and the sixth semiconductor pattern SP6 of the sixth transistor T6 located on different respective layers may be electrically connected to each other through the (1-2)-th connection electrode CNE12.

The (1-3)-th connection electrode CNE13 may be connected to the third source S3 of the third transistor T3. The (1-3)-th connection electrode CNE13 may be connected to the third source S3 through a contact hole penetrating the fifth and sixth insulating layers 50 and 60.

The display panel DP includes a valley hole VA-H defined inside the circuit element layer DP-CL. A region in which the valley hole VA-H is located may be defined as a boundary region BA. Referring to FIGS. 6 and 7 together, the boundary region BA in which the valley hole VA-H is located may extend in the first direction DR1, and may be located between two pixel regions PXA-1 and PXA-2 adjacent to each other in the second direction DR2. The valley hole VA-H may extend in the first direction DR1, and may be located between two pixel regions PXA-1 and PXA-2 adjacent to each other. The valley hole VA-H may extend in the first direction DR1, and may be located on both sides of each of the pixel regions PXA-1 and PXA-2 with respect to the second direction DR2. The valley hole VA-H may have, inside the circuit element layer DP-CL, a shape in which the pixel region PXA-1 or PXA-2 is surrounded on both sides with respect to the second direction DR2, thereby absorbing an external impact added on a region surrounded by the valley hole VA-H, and reducing or minimizing transmission of the external impact to adjacent pixels.

The valley hole VA-H may at least partially penetrate the lower insulating layers 10, 20, 30, 40, 50, and 60 of the circuit element layer DP-CL. The valley hole VA-H may penetrate two or more insulating layers of the lower insulating layers 10, 20, 30, 40, 50, and 60 of the circuit element layer DP-CL. In one or more embodiments, the valley hole VA-H may at least penetrate the fifth insulating layer 50 and the sixth insulating layer 60. The inside of the valley hole VA-H is filled with at least a portion of the plurality of insulating layers of the circuit element layer DP-CL.

FIG. 7 illustrates the valley hole VA-H penetrating the fourth to sixth insulating layers 40, 50, and 60 and filled with the seventh insulating layer 70. However, a thickness, in a thickness direction of the display panel DP, by which the valley hole VA-H penetrates is not limited thereto, and the valley hole VA-H may be formed to penetrate other insulating layers of the first to sixth insulating layers 10, 20, 30, 40, 50, and 60. The number and the shape of insulating layers penetrated by the valley hole VA-H may be different according to a process condition in which the valley hole VA-H is formed, and is not particularly limited.

Meanwhile, as described above, because the boundary region BA is not located between the (1-1)-th pixel region PXA-11 and the (1-2)-th pixel region PXA-12, a separate valley hole VA-H is not defined between the (1-1)-th pixel region PXA-11 and the (1-2)-th pixel region PXA-12. That is, the lower insulating layers 10, 20, 30, 40, 50, and 60 overlapping each of the (1-1)-th pixel region PXA-11 and the (1-2)-th pixel region PXA-12 may have a continuous shape without being cut by the valley hole VA-H.

The first conductive pattern CDP1 is located in the boundary region BA. The first conductive pattern CDP1 overlaps the valley hole VA-H, and is at least partially located in the valley hole VA-H. The first conductive pattern CDP1 may be located inside the valley hole VA-H to be in contact with an inner side surface defining the valley hole VA-H. The first conductive pattern CDP1 may entirely cover the inner side surface of the valley hole VA-H.

The seventh insulating layer 70 may be located on the sixth insulating layer 60. The seventh insulating layer 70 may cover the fourth conductive pattern layer. For example, the seventh insulating layer 70 may cover the (1-1)-th to (1-3)-th connection electrodes CNE11, CNE12, and CNE13 and the first conductive pattern CDP1. The seventh insulating layer 70 may fill inside the valley hole VA-H to cover an outer side surface of the first conductive pattern CDP1 located on the inner side surface of the valley hole VA-H. Meanwhile, in the present specification, the seventh insulating layer 70 may be described as “a first organic layer.”

A fifth conductive pattern layer may be located on the seventh insulating layer 70. The second connection electrode CNE2 may be formed from the fifth conductive pattern layer. In addition, in one or more embodiments, signal lines included in the display panel DP may be partially formed from the fifth conductive pattern layer.

The second connection electrode CNE2 may be connected to the (1-1)-th connection electrode CNE11 through a contact hole penetrating the seventh insulating layer 70. The second connection electrode CNE2 may be connected to the sixth drain D6 of the sixth transistor T6 through the (1-1)-th connection electrode CNE11. However, the present disclosure is not limited thereto, and the second connection electrode CNE2 may be omitted, or an additional connection electrode located between the second connection electrode CNE2 and the (1-1)-th connection electrode CNE11 may be further located in the circuit element layer DP-CL.

The eighth insulating layer 80 may be located on the seventh insulating layer 70. The eighth insulating layer 80 may cover the fifth conductive pattern layer. For example, the eighth insulating layer 80 may cover the second connection electrode CNE2. Meanwhile, in the present specification, the eighth insulating layer 80 may be described as “a second organic layer.”

At least any one of the seventh insulating layer 70 and the eighth insulating layer 80 may include an organic layer. The organic layer may supply a substantially flat surface, covering particles existing on a surface of a layer located under the organic layer, or covering a step between components located under the organic layer. In addition, the organic layer may release a stress between components located on and under the organic layer.

The display element layer DP-OLED may be located on the circuit element layer DP-CL. The display element layer DP-OLED may include a pixel-defining film PDL and light-emitting elements OLED1 and OLED2. The light-emitting elements OLED1 and OLED2 may each include a first electrode AE, a light-emitting layer EM, and a second electrode CE.

The light-emitting elements OLED1 and OLED2 may include an organic light-emitting element, a quantum dot light-emitting element, a micro-LED light-emitting element, or a nano LED light-emitting element. However, the present disclosure is not limited thereto, and the light-emitting elements OLED1 and OLED2 may include various embodiments as long as emitting light or controlling an amount of the light in response to an electrical signal.

The light-emitting elements OLED1 and OLED2 may each electrically connected to a transistor of the corresponding pixel circuit PDC (see FIG. 5). FIG. 7 illustrates that the light-emitting elements OLED1 and OLED2 are electrically connected to the corresponding sixth transistor T6.

The first electrodes AE of the light-emitting elements OLED1 and OLED2 may be located on the uppermost layer of the circuit element layer DP-CL. For example, the first electrodes AE may be located on the eighth insulating layer 80. The first electrodes AE may be spaced apart from each other on the eighth insulating layer 80. The first electrodes AE may be respectively connected to the corresponding second connection electrodes CNE2 through contact holes penetrating the eighth insulating layer 80. The first electrodes AE may be respectively electrically connected to the corresponding sixth drains D6 through the corresponding second connection electrode CNE2 and (1-1)-th connection electrode CNE11.

The pixel-defining film PDL may be located on the uppermost layer of the circuit element layer DP-CL. For example, the pixel-defining film PDL may be located on the eighth insulating layer 80. Pixel openings PX-OP that partially expose the corresponding first electrode AE respectively overlapping the first electrode AE may be defined in the pixel-defining film PDL. Regions of the first electrodes AE exposed by the pixel openings PX-OP may correspond to light-emitting regions PXA. That is, the display region D-DA of the display panel DP may include the light-emitting regions PXA. A region in which the pixel-defining film PDL is located may correspond to a non-light-emitting region NPXA. On a plane, the non-light-emitting region NPXA may surround the light-emitting regions PXA, and may set a boundary of the light-emitting regions PXA.

The pixel-defining film PDL may include a polymer resin. For example, the pixel-defining film PDL may include a polyacrylate-based resin, or a polyimide-based resin. However, the present disclosure is not limited thereto, and the pixel-defining film PDL may further include an inorganic material.

The pixel-defining film PDL may further include a light-absorbing material. For example, the pixel-defining film PDL may include a black coloring agent, such as a black pigment, or black dye. For example, the black coloring agent may include carbon black, metal, such as chromium, or an oxide thereof, but the present disclosure is not limited thereto.

Light-emitting layers EM1 and EM2 may be located on the first electrode AE. The light-emitting layers EM of the light-emitting elements OLED1 and OLED2 may be respectively located corresponding to the pixel openings PX-OP, and may be formed as light-emitting patterns spaced apart from each other on a plane. However, the present disclosure is not limited thereto, and the light-emitting layers EM1 and EM2 of the light-emitting elements OLED1 and OLED2 may be formed as an integrated film, and a common layer. The light-emitting layers EM1 and EM2 may include an organic light-emitting material and/or an inorganic light-emitting material. For example, the light-emitting layers EM1 and EM2 may include a fluorescent material, a phosphorescent material an organometallic complex light-emitting material, or a quantum dot. The light-emitting layers EM1 and EM2 may emit light having any one color of a red color, a green color, or a blue color.

A second electrode CE may be located on the light-emitting layers EM1 and EM2. The second electrode CE of the light-emitting elements OLED1 and OLED2 may be provided as an integrated common layer, and may overlap the light-emitting regions PXA and the non-light-emitting region NPXA. The second electrode CE may be commonly located in the pixels PX (see FIG. 4) to supply a common voltage.

Meanwhile, the light-emitting elements OLED1 and OLED2 may further include a light emission control layer located between the first electrode AE and the second electrode CE. For example, the light emission control layer may include a hole control layer located between the first electrode AE and the light-emitting layers EM1 and EM2, or an electron control layer located between the light-emitting layers EM1 and EM2 and the second electrode CE. The hole control layer may include at least one of a hole injection layer, a hole transport layer, or an electron-blocking layer, and the electron control layer may include at least one of an electron injection layer, an electron transport layer, or a hole-blocking layer.

The encapsulation layer TFE may be located on the display element layer DP-OLED. The encapsulation layer TFE may seal the light-emitting elements OLED1 and OLED2. The encapsulation layer TFE may include at least one thin-film of an inorganic film and an organic film. In one or more embodiments, the encapsulation layer TFE may include inorganic films, and an organic film located between the inorganic films.

The inorganic film of the encapsulation layer TFE may protect the light-emitting elements OLED1 and OLED2 from moisture and/or oxygen. The inorganic film may include at least one of aluminum oxide, titanium oxide, silicon oxide, silicon nitride, silicon oxynitride, zirconium oxide, or hafnium oxide. However, a material of the inorganic film is not limited thereto.

The organic film of the encapsulation layer TFE may protect the light-emitting elements OLED1 and OLED2 from foreign matters, such as dust particles. The organic film may include an acrylic resin. However, a material of the organic film is not limited to the above example.

The first driving voltage ELVDD (see FIG. 5) may be applied to the first electrode AE, and the second driving voltage ELVSS (see FIG. 5) may be applied to the second electrode CE. When an exciton is formed by combining a hole and an electron injected to the light-emitting layer EM, and the exciton transitions to a ground state, the light-emitting elements OLED1 and OLED2 may emit light. The light-emitting elements OLED1 and OLED2 may emit light in response to an applied electrical signal, so that the display panel DP may display an image through the display region D-DA.

FIGS. 8A to 8G are plan views illustrating a sequential stack structure of patterns constituting a pixel PXij (see FIG. 5). FIGS. 8A to 8G illustrate the sequential stack structure of a portion of the pixel regions PXA-1 and PXA-2 described in FIGS. 6 and 7, and some patterns included in a boundary region BA adjacent thereto. Meanwhile, a shape and an arrangement of pattern layers constituting a pixel illustrated in FIGS. 8A to 8G are merely examples, and is not necessarily limited thereto.

The circuit element layer DP-CL (see FIG. 7) may include a semiconductor pattern layer and a conductive pattern layer. The semiconductor pattern layer and the conductive pattern layer may each include patterns arranged in a rule (e.g., predetermined rule) on a plane, and the patterns may constitute the pixel circuit PDC (see FIG. 5) and signal lines.

Referring to FIG. 8A, a blocking layer BM may be located on the base substrate BS (see FIG. 7). The blocking layer BM may include a blocking pattern BML. The blocking layer BM may include metal. For example, the blocking layer BM may include molybdenum. Because the blocking layer BM is located under a semiconductor pattern included in each of first to seventh transistors T1, T2, T3, T4, T5, T6, and T7, the blocking layer BM may function to shield light incident from the outside. In addition, the blocking layer BM may block electric potential due to a polarization phenomenon between the first to eighth insulating layers 10, 20, 30, 40, 50, 60, 70, and 80 (see FIG. 7) described above from affecting the first to seventh transistors T1, T2, T3, T4, T5, T6, and T7 (see FIG. 5).

Referring to FIG. 8B, a first semiconductor pattern layer SM1 may be located on the blocking layer BM in FIG. 8A. The first semiconductor pattern layer SM1 may include first, second, fifth, sixth, and seventh semiconductor patterns SP1, SP2, SP5, SP6, and SP7. An insulating layer (for example, the first insulating layer 10 in FIG. 7) may be located between the first semiconductor pattern layer SM1 and the blocking pattern BML. The first semiconductor pattern layer SM1 may be located on the base layer SUB (see FIG. 7) to include a semiconductor material. For example, the first semiconductor pattern layer SM1 may include amorphous silicon or polycrystalline silicon. In the present specification, the first semiconductor pattern layer SM1 including the first, second, fifth, sixth, and seventh semiconductor patterns SP1, SP2, SP5, SP6, and SP7 may be referred to as “a semiconductor pattern layer.”

The first semiconductor pattern layer SM1 may include a plurality of regions having different doping concentrations. A region, of the first semiconductor pattern layer SM1, having a greater conductivity may correspond to a source or a drain of a transistor, and a region, of the first semiconductor pattern layer SM1, having a smaller conductivity may correspond to a channel of the transistor.

The first semiconductor pattern SP1 may include a first source S1, a first drain D1, and a first channel A1. The second semiconductor pattern SP2 may include a second source S2, a second drain D2, and a second channel A2. The fifth semiconductor pattern SP5 may include a fifth source S5, a fifth drain D5, and a fifth channel A5. The sixth semiconductor pattern SP6 may include a sixth source S6, a sixth drain D6, and a sixth channel A6. The seventh semiconductor pattern SP7 may include a seventh source S7, a seventh drain D7, and a seventh channel A7. The first, second, fifth, sixth, and seventh channels A1, A2, A5, A6, and A7 may be respectively located between the first, second, fifth, sixth, and seventh sources S1, S2, S5, S6, and S7 and the first, second, fifth, sixth, and seventh drains D1, D2, D5, D6, and D7.

The first, second, fifth, sixth, and seventh semiconductor patterns SP1, SP2, SP5, SP6, and SP7 constituting the pixel circuit PDC (see FIG. 5) may be arranged in the first direction DR1 and the second direction DR2 on a plane. The first, second, fifth, sixth, and seventh semiconductor patterns SP1, SP2, SP5, SP6, and SP7 may be integrally formed. The first, second, fifth, sixth, and seventh semiconductor patterns SP1, SP2, SP5, SP6, and SP7 may be repeatedly arranged having a symmetric structure in the first direction DR1. However, the present disclosure is not limited thereto, and the first, second, fifth, sixth, and seventh semiconductor patterns SP1, SP2, SP5, SP6, and SP7 having the same structure may be repeatedly arranged in the first direction DR1.

The first semiconductor pattern SP1 may be connected to the second semiconductor pattern SP2, to the fifth semiconductor pattern SP5, and to the sixth semiconductor pattern SP6. The first source S1 of the first semiconductor pattern SP1 and the second drain D2 of the second semiconductor pattern SP2 may be integrally formed to be electrically connected to each other. The first source S1 of the first semiconductor pattern SP1 and the fifth drain D5 of the fifth semiconductor pattern SP5 may be integrally formed to be electrically connected to each other. A point at which the first semiconductor pattern SP1, the second semiconductor pattern SP2, and the fifth semiconductor pattern SP5 are connected to each other may correspond to the second node ND2 (see FIG. 5). The first drain D1 of the first semiconductor pattern SP1 and the sixth source S6 of the sixth semiconductor pattern SP6 may be integrally formed to be electrically connected to each other. A point at which the first semiconductor pattern SP1 and the sixth semiconductor pattern SP6 are connected to each other may correspond to the third node ND3 (see FIG. 5).

The sixth drain D6 of the sixth semiconductor pattern SP6 and the seventh source S7 of the seventh semiconductor pattern SP7 may be integrally formed to be electrically connected to each other. A point at which the sixth semiconductor pattern SP6 and the seventh semiconductor pattern SP7 are connected to each other may correspond to the fourth node ND4 (see FIG. 5).

Referring to FIG. 8C, a first conductive pattern layer MP1 may be located on the first semiconductor pattern layer SM1 in FIG. 8B. An insulating layer (for example, the second insulating layer 20 in FIG. 7) may be located between the first conductive pattern layer MP1 and the first semiconductor pattern layer SM1 (see FIG. 8B). The first conductive pattern layer MP1 may include a first gate electrode G1, a light-emitting line EL, and a first scanning line GW.

The first gate electrode G1 may be located on the first semiconductor pattern SP1. The first gate electrode G1 may overlap the first channel A1 on a plane. The first semiconductor pattern SP1 and the first gate electrode G1 may constitute the first transistor T1, and the first gate electrode G1 may correspond to a first gate of the first transistor T1.

The light-emitting line EL may extend in the first direction DR1 to overlap the fifth semiconductor pattern SP5 and the sixth semiconductor pattern SP6 on a plane. A portion, of the light-emitting line EL, overlapping the fifth semiconductor pattern SP5 may correspond to a fifth gate electrode G5 of the fifth transistor T5, and another portion, of the light-emitting line EL, overlapping the sixth semiconductor pattern SP6 may correspond to a sixth gate electrode G6 of the sixth transistor T6. On a plane, the fifth gate electrode G5 may overlap the fifth channel A5 (see FIG. 8B), and the sixth gate electrode G6 may overlap the sixth channel A6 (see FIG. 8B).

The first scanning line GW may extend in the first direction DR1 to be spaced apart from the light-emitting line EL in the second direction DR2. The first scanning line GW may overlap the second semiconductor pattern SP2 and the seventh semiconductor pattern SP7 on a plane. A portion of the first scanning line GW may correspond to a second gate electrode G2 of the second transistor T2. Another portion of the first scanning line GW, which overlaps the seventh semiconductor pattern SP7, may correspond to a seventh gate electrode G7 of the seventh transistor T7. On a plane, the second gate electrode G2 may overlap the second channel A2 (see FIG. 8B), and the seventh gate electrode G7 may overlap the seventh channel A7 (see FIG. 8B).

The first conductive pattern layer MP1 may include metal, an alloy, a conductive metal oxide, a transparent conductive material, or the like. For example, the first conductive pattern layer MP1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium-tin oxide (ITO), indium-zinc oxide (IZO), or the like, but is not limited thereto. Description for a material included in the conductive pattern layer may be also applied to other conductive pattern layers to be described later.

Referring to FIG. 8D, a second conductive pattern layer MP2 may be located on the first conductive pattern layer MP1 in FIG. 8C. An insulating layer (for example, the third insulating layer 30 in FIG. 7) may be located between the first conductive pattern layer MP1 (see FIG. 8C) and the second conductive pattern layer MP2. The second conductive pattern layer MP2 may include an upper electrode UE, a second sub-scanning line GCa, a third sub-scanning line GIa, and a first initialization line VIL1.

The upper electrode UE may overlap the first gate electrode G1 (see FIG. 8C). The upper electrode UE may form the capacitor CAP (see FIG. 5) with the first gate electrode G1. The upper electrode UE overlapping the first gate electrode G1 may correspond to a first electrode of the capacitor CAP, and the first gate electrode G1 may correspond to a second electrode of the capacitor CAP (see FIG. 5). The first electrode of the capacitor CAP and the first gate electrode G1 may be formed as an integrated electrode to be electrically connected to each other.

An opening UE-O penetrating the upper electrode UE may be defined in the upper electrode UE. The first gate electrode G1 may be partially exposed by the opening UE-O of the upper electrode UE.

The second sub-scanning line GCa may extend in the first direction DR1. The second sub-scanning line GCa may correspond to the second scanning line GCi (see FIG. 5) to which the compensation scanning signal GCSi (see FIG. 5) is applied. In one or more embodiments, the second scanning line GCi may be a line having a double layer, to which the same signal is applied. The second sub-scanning line GCa may be a portion of the second scanning line GCi. However, the present disclosure is not limited thereto, and the second scanning line GCi may be provided as a single-layered line.

The third sub-scanning line GIa may extend in the first direction DR1, and may be spaced apart from the second sub-scanning line GCa in the second direction DR2. The third sub-scanning line GIa may correspond to the third scanning line GIi (see FIG. 5) to which the initialization scanning signal GISi (see FIG. 5) is applied. In one or more embodiments, the third scanning line GIi may be a line having a double layer, the same signal being applied to both layers. The third sub-scanning line GIa may be a portion of the third scanning line GIi. However, the present disclosure is not limited thereto, and the third scanning line GIi may be provided as a single layered line.

The first initialization line VIL1 may extend in the first direction DR1, and may be spaced apart from the second sub-scanning line GCa and the third sub-scanning line GIa in the second direction DR2. A first initialization voltage Vint1 may be applied to the first initialization line VIL1.

Referring to FIG. 8E, a second semiconductor pattern layer SM2 may be located on the second conductive pattern layer MP2 in FIG. 8D. An insulating layer (for example, the fourth insulating layer 40 in FIG. 7) may be located between the second semiconductor pattern layer SM2 and the second conductive pattern layer MP2. The second semiconductor pattern layer SM2 may include third and fourth semiconductor patterns SP3 and SP4. The second semiconductor pattern layer SM2 may include a semiconductor material. For example, the second semiconductor pattern layer SM2 may include a semiconductor material that is different from the first semiconductor pattern layer SM1 (see FIG. 8B). The second semiconductor pattern layer SM2 may include a metal oxide, and the first semiconductor pattern layer SM1 (see FIG. 8B) may include silicon. However, as long as the second semiconductor pattern layer SM2 includes a semiconductor material, the present disclosure is not limited.

The second semiconductor pattern layer SM2 may include a plurality of regions having different respective conductivities according to whether or not the metal oxide is reduced. A region of the second semiconductor pattern layer SM2 having a greater conductivity may correspond to a source or a drain of a transistor, and a region of the second semiconductor pattern layer SM2 having a smaller conductivity may correspond to a channel of the transistor.

The third semiconductor pattern SP3 may include a third source S3, a third drain D3, and a third channel A3. The third channel A3 may be located between the third source S3 and the third drain D3. The fourth semiconductor pattern SP4 may include a fourth source S4, a fourth drain D4, and a fourth channel A4. The fourth channel A4 may be located between the fourth source S4 and the fourth drain D4.

The third and fourth semiconductor patterns SP3 and SP4 constituting the pixel circuit PDC (see FIG. 5) may be arranged in the first direction DR1 and the second direction DR2 on a plane. The third and fourth semiconductor patterns SP3 and SP4 may be repeatedly arranged having a symmetric structure in the first direction DR1. However, the present disclosure is not limited thereto, and the third and fourth semiconductor patterns SP3 and SP4 having the same structure may be repeatedly arranged in the first direction DR1.

The third semiconductor pattern SP3 may be connected to the fourth semiconductor pattern SP4. The third source S3 of the third semiconductor pattern SP3 and the fourth drain D4 of the fourth semiconductor pattern SP4 may be integrally formed to be electrically connected to each other. A point at which the third semiconductor pattern SP3 and the fourth semiconductor pattern SP4 are connected to each other may correspond to the first node ND1 (see FIG. 5).

The third semiconductor pattern SP3 may at least partially overlap the first conductive pattern layer MP1 (see FIG. 8B) or the second conductive pattern layer MP2 (see FIG. 8D) on a plane. The third channel A3 of the third semiconductor pattern SP3 may overlap the second sub-scanning line GCa located thereunder. The second sub-scanning line GCa overlapping the third channel A3 may partially correspond to a third gate. In addition, the first scanning line GW and a portion of the second sub-scanning line GCa overlapping the third semiconductor pattern SP3 may protect the third semiconductor pattern SP3 from light introduced to the lower portion thereof.

The fourth semiconductor pattern SP4 may at least partially overlap the first conductive pattern layer MP1 (see FIG. 8C) or the second conductive pattern layer MP2 (see FIG. 8D) on a plane. The fourth channel A4 of the fourth semiconductor pattern SP4 may overlap the third sub-scanning line GIa located thereunder. A portion of the third sub-scanning line GIa overlapping the fourth channel A4 may correspond to a fourth gate. In addition, the third sub-scanning line GIa and a portion of the first initialization line VIL1 overlapping the fourth semiconductor pattern SP4 may protect the fourth semiconductor pattern SP4 from light introduced to the lower portion thereof.

Referring to FIG. 8F, a third conductive pattern layer MP3 may be located on the second semiconductor pattern layer SM2 in FIG. 8E. An insulating layer (for example, the fifth insulating layer 50 in FIG. 7) may be located between the third conductive pattern layer MP3 and the second semiconductor pattern layer SM2 (see FIG. 8E). The third conductive pattern layer MP3 may include a second sub-scanning line GCb and a third sub-scanning line GIb.

The second sub-scanning line GCb may extend in the first direction DR1. The second sub-scanning line GCb may correspond to the second scanning line GCi (see FIG. 5) to which the compensation scanning signal GCSi (see FIG. 5) is applied. The second sub-scanning line GCb of the third conductive pattern layer MP3 and the second sub-scanning line GCa of the second conductive pattern layer MP2 (see FIG. 8D) may overlap each other on a plane. The second sub-scanning lines GCa and GCb located on different layers may be electrically connected to each other, and the same signal may be applied thereto. That is, in one or more embodiments, the second scanning line GCi may be a line having a double layer, to which the same signal is applied, and the second sub-scanning line GCb may be a portion thereof. However, the present disclosure is not limited thereto, and one of the second sub-scanning lines GCa and GCb may be omitted.

The second sub-scanning line GCb of the third conductive pattern layer MP3 may overlap the third semiconductor pattern SP3 on a plane. A portion of the second sub-scanning line GCb overlapping the third semiconductor pattern SP3 may correspond to the third gate electrode G3 of the third transistor T3. On a plane, the third gate electrode G3 may overlap the third channel A3 (see FIG. 8E). The third channel A3 may overlap each of the second sub-scanning line GCa located under the third semiconductor pattern SP3, and the second sub-scanning line GCb located on the third semiconductor pattern SP3. The third gate of the third transistor T3 may be doubly formed to have a sufficient gate charge, and may be switched at relatively a high speed.

The third sub-scanning line GIb may extend in the first direction DR1. The third sub-scanning line GIb may correspond to the third scanning line GIi (see FIG. 5) to which the initialization scanning signal GISi (see FIG. 5) is applied. The third sub-scanning line GIb of the third conductive pattern layer MP3 and the third sub-scanning line GIa of the second conductive pattern layer MP2 (see FIG. 8D) may overlap each other on a plane. The third sub-scanning lines GIa and GIb located on different layers may be electrically connected to each other, and the same signal may be applied thereto. That is, in one or more embodiments, the third scanning line GIi (see FIG. 5) may be a line having a double layer, to which the same signal is applied, and the third sub-scanning line GIb may be a portion thereof. However, the present disclosure is not limited thereto, and one of the third sub-scanning lines GIa and GIb may be omitted.

The third sub-scanning line GIb of the third conductive pattern layer MP3 may overlap the fourth semiconductor pattern SP4 on a plane. A portion of the third sub-scanning line GIb overlapping the fourth semiconductor pattern SP4 may correspond to the fourth gate electrode G4 of the fourth transistor T4. On a plane, the fourth gate electrode G4 may overlap the fourth channel A4. The fourth channel A4 may overlap each of the third sub-scanning line GIb located under the fourth semiconductor pattern SP4, and the third sub-scanning line GIb located on the fourth semiconductor pattern SP4. The fourth gate of the fourth transistor T4 may be doubly formed to have a sufficient gate charge, and may be switched at a relatively high speed.

Referring to FIG. 8G, a fourth conductive pattern layer MP4 may be located on the third conductive pattern layer MP3 in FIG. 8F. An insulating layer (for example, the sixth insulating layer 60 in FIG. 7) may be located between the third conductive pattern layer MP3 (see FIG. 8E) and the fourth conductive pattern layer MP4. The fourth conductive pattern layer MP4 may include connection electrodes CNE11, CNE12, CNE13, CNE14, CNE15, CNE16, and CNE17 spaced apart from each other on the same layer. The fourth conductive pattern layer MP4 may include the first conductive pattern CDP1.

The connection electrodes CNE11, CNE12, CNE13, CNE14, CNE15, CNE16, and CNE17 may be electrodes electrically connecting configurations respectively connected to the connection electrodes. The connection electrodes CNE11, CNE12, CNE13, CNE14, CNE15, CNE16, and CNE17 may respectively overlap the configurations respectively connected to the connection electrodes. The connection electrodes CNE11, CNE12, CNE13, CNE14, CNE15, CNE16, and CNE17 may be connected penetrating at least one insulating layer located between the connection electrodes CNE11, CNE12, CNE13, CNE14, CNE15, CNE16, and CNE17 and the configurations respectively connected thereto. The connection electrodes CNE11, CNE12, CNE13, CNE14, CNE15, CNE16, and CNE17 may include (1-1)-th to (1-7)-th connection electrodes.

The connection electrodes CNE11, CNE12, CNE13, CNE14, CNE15, CNE16, and CNE17 may include metal, an alloy, a conductive metal oxide, and/or the like. For example, the connection electrodes CNE11, CNE12, CNE13, CNE14, CNE15, CNE16, and CNE17 may include aluminum (A1), an alloy containing aluminum, titanium (Ti), an alloy containing titanium, silver (Ag), an alloy containing silver, molybdenum (Mo), an alloy containing molybdenum, aluminum nitride (AlN), tungsten (W), tungsten nitride (WN), copper (Cu), indium-tin oxide (ITO), indium-zinc oxide (IZO), or the like, but is not limited thereto. For example, the connection electrodes CNE11, CNE12, CNE13, CNE14, CNE15, CNE16, and CNE17 may include a three-layered structure of Ti/Al/Ti, but is not limited thereto.

The (1-1)-th connection electrode CNE11 may overlap the sixth semiconductor pattern SP6 (see FIG. 8B) of the sixth transistor T6. The (1-1)-th connection electrode CNE11 may be connected to the sixth drain D6 (see FIG. 8B) of the sixth transistor T6 through a contact hole. The (1-1)-th connection electrode CNE11 may electrically connect the first electrode AE (see FIG. 7) of the light-emitting element OLED (see FIG. 7) located on the (1-1)-th connection electrode CNE11, and the sixth gate electrode G6.

The (1-2)-th connection electrode CNE12 may overlap each of the first semiconductor pattern SP1 (see FIG. 8B) of the first transistor T1 and the third semiconductor pattern SP3 (see FIG. 8D) of the third transistor T3. The (1-2)-th connection electrode CNE12 may be connected to the first drain D1 (see FIG. 8B) of the first transistor T1 and to the third drain D3 (see FIG. 8D) of the third transistor T3 through a contact hole. The first drain D1 (see FIG. 8B) of the first transistor T1 and the third drain D3 (see FIG. 8E) of the third transistor T3 located on different respective layers may be electrically connected to each other through the (1-2)-th connection electrode CNE12. A point at which the first transistor T1, the third transistor T3, and the sixth transistor T6 are electrically connected to each other may correspond to the third node ND3 (see FIG. 5).

The (1-3)-th connection electrode CNE13 may overlap each of the first gate electrode G1 (see FIG. 8B) of the first transistor T1 and the third semiconductor pattern SP3 (see FIG. 8E) of the third transistor T3. The (1-3)-th connection electrode CNE13 may be connected to the first gate electrode G1 (see FIG. 8C) exposed by the opening UE-O of the upper electrode UE. The (1-3)-th connection electrode CNE13 may be connected to the third source S3 (see FIG. 8E) of the third transistor T3. The first gate electrode G1 (see FIG. 8C) of the first transistor T1 and the third source S3 (see FIG. 8E) of the third transistor T3 located on different respective layers may be electrically connected to each other through the (1-3)-th connection electrode CNE13. A point at which the first gate electrode G1 (see FIG. 8B) of the first transistor T1 and the third source S3 (see FIG. 8E) of the third transistor T3 are electrically connected to each other may correspond to the first node ND1 (see FIG. 5).

The (1-4)-th connection electrode CNE14 may overlap each of the upper electrode UE and the fifth semiconductor pattern SP5 (see FIG. 8C) of the fifth transistor T5. The (1-4)-th connection electrode CNE14 may be connected to the upper electrode UE and the fifth source S5 (see FIG. 8B) of the fifth transistor T5. That is, the (1-4)-th connection electrode CNE14 may be electrically connected to the upper electrode UE corresponding to the first electrode of the capacitor CAP (see FIG. 5). The (1-4)-th connection electrode CNE14 may be connected to the first voltage line VL1 (see FIG. 5) located on the (1-4)-th connection electrode CNE14. That is, the upper electrode UE and the fifth source S5 (see FIG. 8B) of the fifth transistor T5 may be electrically connected to the first voltage line VL1 (see FIG. 5) through the (1-4)-th connection electrode CNE14, and the first driving voltage ELVDD (see FIG. 5) may be applied thereto.

The (1-5)-th connection electrode CNE15 may overlap the seventh semiconductor pattern SP7 (see FIG. 8C) of the seventh transistor T7. The (1-5)-th connection electrode CNE15 may be connected to the seventh source S7 (see FIG. 8B) of the seventh transistor T7. The (1-5)-th connection electrode CNE15 may be connected to the second initialization line VIL2 (see FIG. 5) located on the (1-5)-th connection electrode CNE15. That is, the seventh source S7 (see FIG. 8B) of the seventh transistor T7 may be electrically connected to the second initialization line VIL2 (see FIG. 5) through the (1-5)-th connection electrode CNE15, and the second initialization voltage Vint2 (see FIG. 5) may be applied thereto.

The (1-6)-th connection electrode CNE16 may overlap the second semiconductor pattern SP2 (see FIG. 8B) of the second transistor T2. The (1-6)-th connection electrode CNE16 may be connected to the second source S2 (see FIG. 8B) of the second transistor T2. The (1-6)-th connection electrode CNE16 may be connected to the data line DLj (see FIG. 5) located on the (1-6)-th connection electrode CNE16. That is, the second source S2 (see FIG. 8B) of the second transistor T2 may be electrically connected to the data line DLj (see FIG. 5) through the (1-6)-th connection electrode CNE16, and the data voltage Vd (see FIG. 5) may be applied thereto.

The (1-7)-th connection electrode CNE17 may overlap the fourth semiconductor pattern SP4 (see FIG. 8E) of the fourth transistor T4. The (1-7)-th connection electrode CNE17 may be connected to the fourth source S4 (see FIG. 8E) of the fourth transistor T4. The (1-7)-th connection electrode CNE17 may be connected to the first initialization line VIL1 through a line or a connection electrode located on the (1-7)-th connection electrode CNE17. That is, the fourth source S4 (see FIG. 8E) of the fourth transistor T4 may be electrically connected to the first initialization line VIL1 through the (1-7)-th connection electrode CNE17, and the first initialization voltage Vint1 (see FIG. 5) may be applied thereto.

Meanwhile, the display panel DP (see FIG. 7) includes valley holes VA-H located on and under patterns included in the pixel circuit PDC (see FIG. 5). The valley holes VA-H may extend in the first direction DR1, and may be spaced apart from each other in the second direction DR2. The valley holes VA-H may be located on and under the first to seventh transistors T1, T2, T3, T4, T5, T6, and T7 included in the pixel circuit PDC (see FIG. 5) on a plane. As described above, the valley hole VA-H may at least partially penetrate the lower insulating layers 10, 20, 30, 40, 50, and 60 (see FIG. 7). The valley holes VA-H may have a shape in which the pixel circuit PDC (see FIG. 5) is surrounded on both sides of the second direction DR2, thereby absorbing an external impact added on a region surrounded by the valley holes VA-H, and reducing or minimizing transmission of the external impact to pixels located adjacent thereto.

The first conductive pattern CDP1 is located overlapping the valley hole VA-H on a plane. The first conductive pattern CDP1 may extend in the first direction DR1, and may overlap the entire valley hole VA-H on a plane. The first conductive pattern CDP1 may entirely cover the valley hole VA-H on a plane.

The first conductive pattern CDP1 may be included in the fourth conductive pattern layer MP4, like the connection electrodes CNE11, CNE12, CNE13, CNE14, CNE15, CNE16, and CNE17. That is, the first conductive pattern CDP1 may include the same material as the connection electrodes CNE11, CNE12, CNE13, CNE14, CNE15, CNE16, and CNE17. The first conductive pattern CDP1 may be located on the same layer the connection electrodes CNE11, CNE12, CNE13, CNE14, CNE15, CNE16, and CNE17, and may include the same material as the connection electrodes CNE11, CNE12, CNE13, CNE14, CNE15, CNE16, and CNE17.

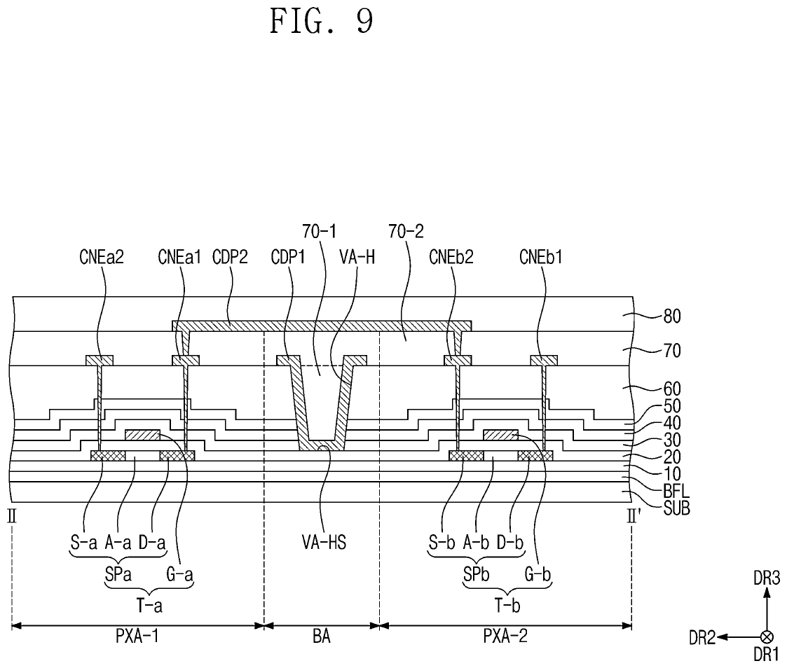

FIG. 9 is a cross-sectional view of a display panel DP according to one or more embodiments of the present disclosure. FIG. 9 illustrates a cross-section taken along the line II-II′ in FIG. 6. FIG. 9 illustrates a cross-section of two adjacent pixel regions PXA-1 and PXA-2 and some configurations in a boundary region BA located therebetween. Meanwhile, for convenience of description, configurations included in the base layer SUB and the circuit element layer DP-CL of those of the display panel DP illustrated in FIG. 7 are illustrated in FIG. 9.

Referring to FIG. 9, a display panel according to one or more embodiments includes the boundary region BA located between the two adjacent pixel regions PXA-1 and PXA-2, and a valley hole VA-H is located in the boundary region BA. The valley hole VA-H may at least partially penetrate lower insulating layers 10, 20, 30, 40, 50, and 60 of the circuit element layer DP-CL. The inside of the valley hole VA-H is filled with at least a portion of a plurality of insulating layers of the circuit element layer DP-CL. For example, as illustrated in FIG. 9, the valley hole VA-H may penetrate third to sixth insulating layers 30, 40, 50, and 60, and may be filled with seventh insulating layer 70. However, the present disclosure is not limited thereto, and the valley hole VA-H may additionally penetrate first and second insulating layers 10 and 20. The valley hole VA-H may additionally penetrate a buffer layer BFL.

A first conductive pattern CDP1 is located in the boundary region BA. The first conductive pattern CDP1 overlaps the valley hole VA-H, and at least a portion thereof is located in the valley hole VA-H. The first conductive pattern CDP1 may be located inside the valley hole VA-H to be in contact with an inner side surface of the valley hole VA-H.

The first conductive pattern CDP1 may cover a valley hole lower surface VA-HS, which is a flat surface exposed by the valley hole VA-H. As in FIG. 9, when the valley hole VA-H penetrates only the third to sixth insulating layers 30, 40, 50, and 60, which are portions of the plurality of lower insulating layers 10, 20, 30, 40, 50, and 60, the first conductive pattern CDP1 may be in contact with the upper surface of the second insulating layer 20 exposed by the valley hole VA-H. Alternatively, when the valley hole VA-H penetrates all of the plurality of lower insulating layers 10, 20, 30, 40, 50, and 60 and the buffer layer BFL, the first conductive pattern CDP1 may be in contact with the upper surface of the exposed base layer SUB.

Meanwhile, the display panel DP according to one or more embodiments may include a first pixel transistor T-a located in the first pixel region PXA-1, and a second pixel transistor T-b located in the second pixel region PXA-2. Description for any one of the first to seventh transistors T1, T2, T3, T4, T5, T6, and T7 (see FIG. 5) described above may be applied to each of the first pixel transistor T-a and the second pixel transistor T-b. Meanwhile, FIG. 9 illustrates that the first pixel transistor T-a and the second pixel transistor T-b have the same structure and disposition relationship as the sixth transistor T6 in FIG. 7, but the present disclosure is not limited thereto, and the first pixel transistor T-a and the second pixel transistor T-b may have the same structure and disposition relationship as the third transistor T3 described in FIG. 7.

The display panel DP may further include connection electrodes CNEa1, CNEa2, CNEb1, and CNEb2. A (1-a)-th connection electrode CNEa1 may be connected to a drain D-a of the first pixel transistor T-a. The (1-a)-th connection electrode CNEa1 may be connected to the drain D-a of the first pixel transistor T-a through a contact hole penetrating second to sixth insulating layers 20, 30, 40, 50, and 60. A (2-a)-th connection electrode CNEa2 may be connected to a source S-a of the first pixel transistor T-a. The (2-a)-th connection electrode CNEa2 may be connected to the source S-a of the first pixel transistor T-a through a contact hole penetrating the second to sixth insulating layers 20, 30, 40, 50, and 60. A (1-b)-th connection electrode CNEb1 may be connected to a drain D-b of the second pixel transistor T-b. The (1-b)-th connection electrode CNEb1 may be connected to the drain D-b of the second pixel transistor T-b through a contact hole penetrating the second to sixth insulating layers 20, 30, 40, 50, and 60. A (2-b)-th connection electrode CNEb2 may be connected to a source S-b of the second pixel transistor T-b. The (2-b)-th connection electrode CNEb2 may be connected to the source S-b of the second pixel transistor T-b through a contact hole penetrating the second to sixth insulating layers 20, 30, 40, 50, and 60.

The first conductive pattern CDP1 may be located on the same layer as the connection electrodes CNEa1, CNEa2, CNEb1, and CNEb2. The connection electrodes CNEa1, CNEa2, CNEb1, and CNEb2 and the first conductive pattern CDP1 may be spaced apart from each other on the same layer. The connection electrodes CNEa1, CNEa2, CNEb1, and CNEb2 and the first conductive pattern CDP1 may include the same material, and may be formed through the same process. In one or more embodiments, the first conductive pattern CDP1 may include aluminum (Al), an alloy containing aluminum, titanium (Ti), an alloy containing titanium, silver (Ag), an alloy containing silver, molybdenum (Mo), an alloy containing molybdenum, aluminum nitride (AlN), tungsten (W), tungsten nitride (WN), copper (Cu), indium-tin oxide (ITO), indium-zinc oxide (IZO), or the like.

A seventh insulating layer 70 may be located on the sixth insulating layer 60. The seventh insulating layer 70 may cover the connection electrodes CNEa1, CNEa2, CNEb1, and CNEb2 and the first conductive pattern CDP1. The seventh insulating layer 70 may fill the inside of the valley hole VA-H to cover an outer side surface of the first conductive pattern CDP1 located on an inner side surface of the valley hole VA-H.

The seventh insulating layer 70 may include a layer portion 70-2 located on the sixth insulating layer 60, and a filling portion 70-1 located inside the valley hole VA-H. The filling portion 70-1 may be located inside the valley hole VA-H to fill the valley hole VA-H, and may cover an outer side surface of the first conductive pattern CDP1 covering an inner side surface of the valley hole VA-H. The layer portion 70-2 and the filling portion 70-1 may have an integrated shape. In a display panel according to one or more embodiments, a separate pattern for filling the inside of the valley hole VA-H may not be supplied, and in a process of forming the seventh insulating layer 70 located on the sixth insulating layer 60, a portion of the seventh insulating layer 70 including an organic material may fill the inside of the valley hole VA-H, and the rest of the seventh insulating layer 70 may form a layered structure on the sixth insulating layer 60.

The display panel DP may further include a second conductive pattern CDP2. At least a portion of the second conductive pattern CDP2 may overlap the boundary region BA. The portion of the second conductive pattern CDP2 may overlap the boundary region BA, and the rest of the second conductive pattern CDP2 may overlap each of the two adjacent pixel regions PXA-1 and PXA-2 in the second direction DR2. The second conductive pattern CDP2 may electrically connect the first pixel transistor T-a and the second pixel transistor T-b respectively located on the two adjacent pixel regions PXA-1 and PXA-2 in the second direction DR2. An end of the second conductive pattern CDP2 may be connected to the (1-a)-th connection electrode CNEa1 to be electrically connected to the drain D-a of the first pixel transistor T-a. The other end of the second conductive pattern CDP2 may be connected to the (2-a)-th connection electrode CNEa2 to be electrically connected to the source S-a of the first pixel transistor T-a.

The second conductive pattern CDP2 may be located on the seventh insulating layer 70. The second conductive pattern CDP2 may be located at the same layer as the second connection electrode CNE2 (see FIG. 7) described above. The second conductive pattern CDP2 may include the same material, and may be formed through the same process as the second connection electrode CNE2 (see FIG. 7).

The eighth insulating layer 80 may be located on the seventh insulating layer 70. The eighth insulating layer 80 may cover the second conductive pattern CDP2.

A display panel according to one or more embodiments may include a boundary region in which a valley hole extending in a first direction is located, and may have a shape in which valley holes surrounds a pixel circuit located in a pixel region on both side of a second direction, thereby absorbing an external impact added on a region surrounded by the valley holes, and reducing or minimizing transmission of the external impact to pixels located adjacent thereto. Meanwhile, the display panel according to one or more embodiments may include a first conductive pattern covering an inner side surface of the valley hole, thereby reducing or preventing the likelihood of a crack or the like capable of being generated in a process of forming the valley hole or in following processes, and reducing or preventing external moisture introduced to the lower portion of the valley hole. Accordingly, durability and reliability of the display panel may be improved.

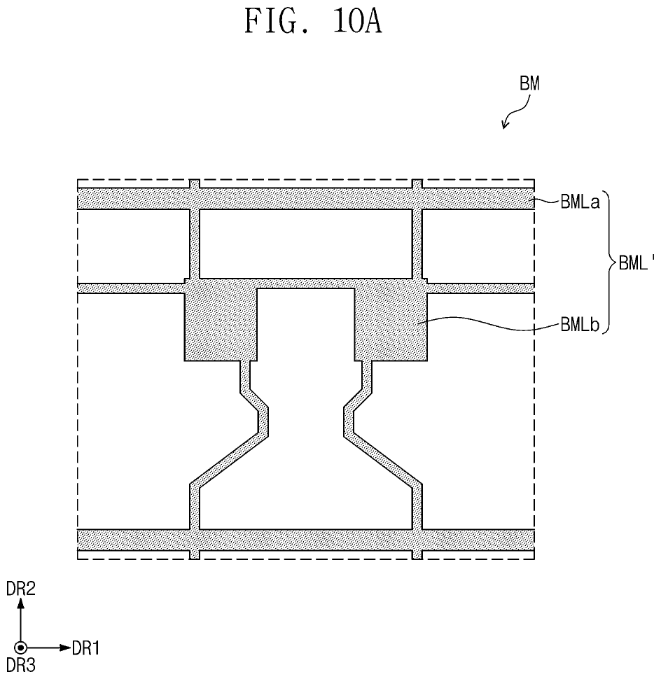

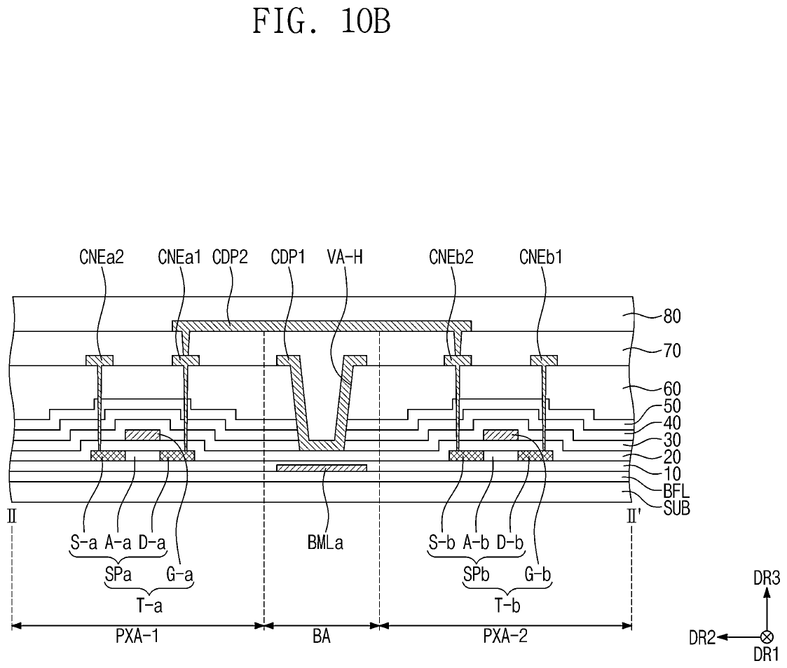

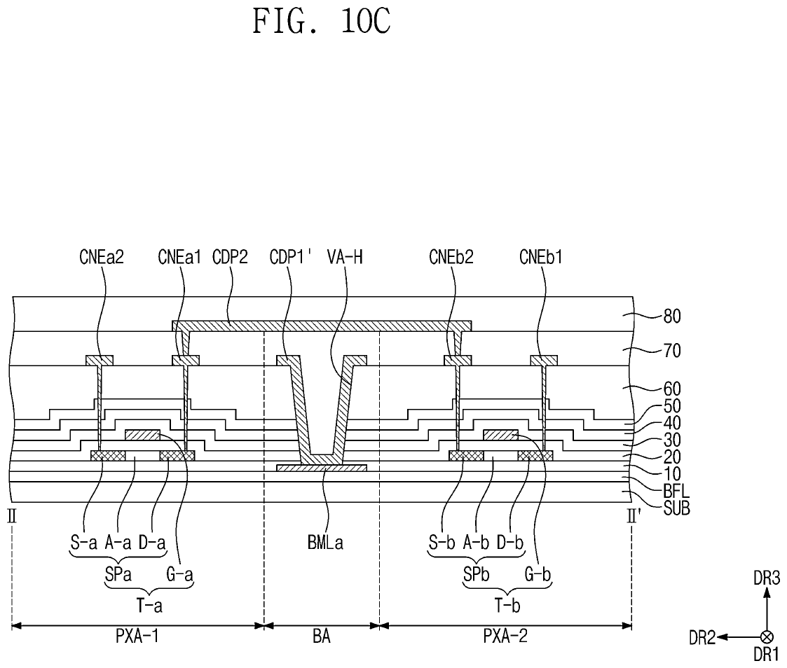

FIG. 10A is a plan view of some configurations of a display panel according to one or more embodiments of the present disclosure. FIGS. 10B and 10C are cross-sectional views of the display panel according to one or more embodiments of the present disclosure. FIG. 10A illustrates a planar shape of a blocking layer, according to one or more embodiments, different from the blocking layer BM illustrated in FIG. 8A described above. FIGS. 10B and 10C illustrate cross-sections of a display panel, according to one or more embodiments, different from a cross-section in FIG. 9 described above.

Referring to FIG. 10A, a blocking layer BM may include a blocking pattern BML′, and the blocking pattern BML′ may include a first blocking pattern BMLa and a second blocking pattern BMLb. The blocking layer BM may include metal. For example, the blocking layer BM may include molybdenum.

As described above, the second blocking pattern BMLb may be located under first to seventh transistors T1, T2, T3, T4, T5, T6, and T7 to function to shield light incident from the outside to the first to seventh transistors T1, T2, T3, T4, T5, T6, and T7. In addition, the second blocking pattern BMLb may block electric potential due to a polarization phenomenon between the first to eighth insulating layers 10, 20, 30, 40, 50, 60, 70, and 80 (see FIG. 7) described above from affecting the first to seventh transistors T1, T2, T3, T4, T5, T6, and T7 (see FIG. 5).

The first blocking pattern BMLa may be located overlapping the boundary region BA (see FIG. 10B). The first blocking pattern BMLa may be included in the same blocking layer BM as the second blocking pattern BMLb, and may be formed through the same process, and may include the same material as the second blocking pattern BMLb. The first blocking pattern BMLa and the second blocking pattern BMLb may have an integrated shape.

As illustrated in FIG. 10B, the first blocking pattern BMLa may be located in the boundary region BA, and may overlap the valley hole VA-H on a plane. The first blocking pattern BMLa may overlap the first conductive pattern CDP1 on a plane. The display panel DP according to one or more embodiments may further include the first blocking pattern BMLa located under the first conductive pattern CDP1, thereby reducing or preventing the likelihood of a crack propagating by the first blocking pattern BMLa when the crack is generated in insulating layers under the valley hole VA-H.

Meanwhile, as illustrated in FIG. 10C, the valley hole VA-H may penetrate all of the first to sixth insulating layers 10, 20, 30, 40, 50, and 60, and thus a first conductive pattern CDP1′ may be at least partially in contact with the first blocking pattern BMLa.

A display panel according to one or more embodiments of the present disclosure may include a boundary region in which a valley hole extending in a direction is located, thereby reducing or minimizing transmission of an external impact to pixels located adjacent thereto, and may include a first conductive pattern covering the valley hole, thereby reducing or preventing the likelihood of a crack propagating or external moisture from being introduced. Accordingly, impact resistance and reliability of the display panel, and a display device including the same, may be improved.

In the above, description has been made with reference to preferred embodiments of the present disclosure, but those skilled in the art or those of ordinary skill in the relevant technical field may understand that various modifications and changes may be made to the present disclosure within the scope not departing from the spirit and the technology scope of the present disclosure described in the claims. Therefore, the technical scope of the present disclosure is not limited to the contents described in the detailed description of the specification, but should be determined by the claims, with functional equivalents thereof to be included therein.

What is claimed is:

1. A display panel comprising:
a base layer comprising a boundary region extending in a first direction, a first pixel region adjacent to the boundary region in a second direction crossing the first direction, and a second pixel region spaced apart from the first pixel region with the boundary region therebetween;
lower insulating layers above the base layer, and defining a valley hole corresponding to the boundary region;
a first conductive pattern comprising a portion inside the valley hole;
a first organic layer comprising a portion above the lower insulating layers, and comprising a remaining portion covering the first conductive pattern and filling the valley hole;
pixel circuits respectively overlapping the first pixel region and the second pixel region;
light-emitting elements above the first organic layer, respectively overlapping the first pixel region and the second pixel region, and respectively electrically connected to the pixel circuits; and
a second conductive pattern above the first organic layer, and comprising a portion overlapping the boundary region.

2. The display panel of claim 1, wherein the pixel circuits comprise:
a first pixel transistor overlapping the first pixel region; and
a second pixel transistor overlapping the second pixel region.

3. The display panel of claim 2, wherein the second conductive pattern electrically connects the first pixel transistor and the second pixel transistor.

4. The display panel of claim 2, wherein the first pixel transistor comprises a first semiconductor pattern comprising a first source region, a first drain region, and a first channel region between the first source region and the first drain region,
wherein the second pixel transistor comprises a second semiconductor pattern comprising a second source region, a second drain region, and a second channel region between the second source region and the second drain region,
wherein an end of the second conductive pattern is electrically connected to the first source region or the first drain region, and
wherein another end of the second conductive pattern is electrically connected to the second source region or the second drain region.

5. The display panel of claim 4, wherein the pixel circuits further comprise a first connection electrode electrically connected to the first source region or the first drain region, and
wherein the first conductive pattern is at a same layer as the first connection electrode, and comprises a same material as the first connection electrode.

6. The display panel of claim 5, wherein the pixel circuits further comprise a second connection electrode electrically connected to the first connection electrode, and
wherein the second conductive pattern is at a same layer as the second connection electrode, and comprises a same material as the second connection electrode.

7. The display panel of claim 1, wherein the first conductive pattern contacts an inner side surface of the valley hole.

8. The display panel of claim 1, wherein the valley hole penetrates some of the lower insulating layers, and
wherein a valley hole lower surface is defined as an upper surface of one of the lower insulating layers exposed by the valley hole, or an upper surface of the base layer,
the valley hole lower surface is covered by the first conductive pattern.

9. The display panel of claim 1, wherein the first conductive pattern is configured to transmit a power supply voltage.

10. The display panel of claim 1, further comprising a first blocking pattern under the first conductive pattern, and overlapping a portion of the first conductive pattern on a plane.

11. The display panel of claim 10, further comprising a second blocking pattern overlapping a portion of the pixel circuits on a plane,
wherein the first blocking pattern is at a same layer as the second blocking pattern, and comprises a same material as the second blocking pattern.

12. The display panel of claim 10, wherein a portion of the first conductive pattern contacts an upper surface of the first blocking pattern.

13. The display panel of claim 1, wherein the first pixel region comprises a (1-1)-th pixel region and a (1-2)-th pixel region adjacent to each other in the first direction, and
wherein the boundary region overlaps the (1-1)-th pixel region and the (1-2)-th pixel region in the second direction.

14. The display panel of claim 13, wherein the boundary region is not between the (1-1)-th pixel region and the (1-2)-th pixel region.

15. The display panel of claim 1, wherein the first conductive pattern entirely covers the valley hole.

16. The display panel of claim 1, wherein the first organic layer comprises:
a layer portion above the lower insulating layers; and
a filling portion in the valley hole, and having an integrated shape with the layer portion.

17. The display panel of claim 1, wherein the lower insulating layers comprise:
a first reference insulating layer under the first organic layer; and
a second reference insulating layer under the first reference insulating layer, and
wherein the valley hole penetrates the first reference insulating layer and the second reference insulating layer.

18. The display panel of claim 1, further comprising a second organic layer above the first organic layer, and covering the second conductive pattern,
wherein the light-emitting elements are above the second organic layer.

19. A display panel comprising:
a base layer comprising a boundary region extending in a first direction, a first pixel region adjacent to the boundary region in a second direction crossing the first direction, and a second pixel region spaced apart from the first pixel region with the boundary region therebetween;
lower insulating layers above the base layer, and defining a valley hole corresponding to the boundary region;
a first conductive pattern comprising a portion inside the valley hole;
a first organic layer comprising a portion above the lower insulating layers, and comprising a remaining portion filling the valley hole and covering the first conductive pattern;
pixel circuits respectively overlapping the first pixel region and the second pixel region; and
light-emitting elements above the first organic layer, respectively overlapping the first pixel region and the second pixel region, and respectively electrically connected to the pixel circuits,
wherein the first conductive pattern contacts an inner side surface of the valley hole, and is configured to transmit a power supply voltage.

20. A display device comprising a first non-folding region, a folding region, and a second non-folding region sequentially arranged along a first direction, the display device comprising:
a window;
a display panel under the window; and
a housing under the display panel to accommodate the display panel,
wherein the display panel comprises:
a base layer comprising a boundary region extending in the first direction, a first pixel region adjacent to the boundary region in a second direction crossing the first direction, and a second pixel region spaced apart from the first pixel region with the boundary region therebetween;
lower insulating layers above the base layer, and defining a valley hole corresponding to the boundary region;
a first conductive pattern comprising a portion inside the valley hole;
a first organic layer comprising a portion above the lower insulating layers, and comprising a remaining portion filling the valley hole and covering the first conductive pattern;
pixel circuits respectively overlapping the first pixel region and the second pixel region; and
light-emitting elements above the first organic layer, respectively overlapping the first pixel region and the second pixel region, and respectively electrically connected to the pixel circuits.
